(19) United States
(12) Patent Application Publication
(10) Pub. No.: US 2024/0006368 A1
(43) Pub. Date: Jan. 4, 2024

(54) SEMICONDUCTOR DEVICE

(71) Applicant: ROHM CO., LTD., Kyoto-shi (JP)

(72) Inventor: Takumi KANDA, Kyoto-shi (JP)

(21) Appl. No.: 18/469,351

(22) Filed: Sep. 18, 2023

Related U.S. Application Data
(63) Continuation of application No. PCT/JP2022/019513, filed on May 2, 2022.

(30) Foreign Application Priority Data
May 14, 2021 (JP) 2021-082077
Aug. 19, 2021 (JP) 2021-134310

(51) Int. Cl. H01L 23/00; H01L 25/07; H01L 23/31; H01L 23/495

(52) U.S. Cl. CPC H01L 24/40; H01L 25/072; H01L 23/3142; H01L 23/49503; H01L 23/49524; H01L 24/41; H01L 24/73; H01L 24/48; H01L 24/32; H01L 2224/32245; H01L 2224/4007; H01L 2224/40137; H01L 2224/40257; H01L 2224/40993; H01L 2224/41051; H01L 2224/48245; H01L 2224/73263; H01L 2924/01013; H01L 2924/13091

(57) ABSTRACT

A semiconductor device includes: a semiconductor element including a first electrode; a conductive member including a first bonding part facing the first electrode; a bonding layer interposed between the first electrode and the first bonding part; and a regulator bonded to at least one of the first electrode and the first bonding part. The regulator faces the bonding layer in a direction orthogonal to a thickness direction of the semiconductor element.

### TECHNICAL FIELD

The present disclosure relates to semiconductor devices.

### BACKGROUND ART

JP-A-2016-162773 discloses an example of a semiconductor device (a power module) that includes a plurality of semiconductor elements bonded to a conductive layer. The semiconductor device also includes a plurality of connecting metal members bonded to the conductive layer and the semiconductor elements. This allows the flow of a large electric current through the semiconductor elements.

The semiconductor device disclosed in JP-A-2016-162773, however, has a possibility that a connecting metal member to be bonded to a semiconductor element moves out of alignment with the electrodes of the semiconductor element. Depending on the amount of misalignment, the connecting metal member may cover the gate electrode of the semiconductor element. Then, the connecting metal member makes it difficult to bond a wire to the gate electrode. It is therefore desirable to provide a solution to prevent misalignment of a connecting metal member with an electrode of a semiconductor element and also to provide a solution to accommodate such misalignment.

### BRIEF DESCRIPTION OF THE DRAWINGS

FIG. 1 is a perspective view of a semiconductor device according to a first embodiment of the present disclosure.

FIG. 2 is a plan view of the semiconductor device of FIG. 1.

FIG. 3 is a plan view corresponding to FIG. 2 and shows a sealing resin as transparent.

FIG. 4 is a bottom view of the semiconductor device of FIG. 1.

FIG. 5 is a front view of the semiconductor device of FIG. 1.

FIG. 6 is a right-side view of the semiconductor device of FIG. 1.

FIG. 7 is a sectional view taken along line VII-VII of FIG. 3.

FIG. 8 is a sectional view taken along line VIII-VIII of FIG. 3.

FIG. 9 is a sectional view taken along line IX-IX of FIG. 3.

FIG. 10 is a partially enlarged view of FIG. 7.

FIG. 11 is a partially enlarged view of FIG. 9.

FIG. 12 is a partially enlarged view of FIG. 3, showing a part around a first element.

FIG. 13 is a sectional view taken along line XIII-XIII of FIG. 12.

FIG. 14 is a partially enlarged view of FIG. 3, showing a part around a second element.

FIG. 15 is a sectional view taken along line XV-XV of FIG. 14.

FIG. 16 is a partially enlarged plan view of a semiconductor device according to a second embodiment of the present disclosure, showing a part around a first element and showing a sealing resin as transparent.

FIG. 17 is a sectional view taken along line XVII-XVII of FIG. 16.

FIG. 18 is a partially enlarged plan view of the semiconductor device of FIG. 16, showing a part around a second element and showing the sealing resin as transparent.

FIG. 19 is a sectional view taken along line XIX-XIX of FIG. 18.

FIG. 20 is a partially enlarged plan view of a variation of the semiconductor device of FIG. 16, showing a sealing resin as transparent.

FIG. 21 is a sectional view taken along line XXI-XXI of FIG. 20.

FIG. 22 is a partially enlarged plan view of a semiconductor device according to a third embodiment of the present disclosure, showing a part around a first element and showing a sealing resin as transparent.

FIG. 23 is a partially enlarged plan view of the semiconductor device of FIG. 22, showing a part around a second element and showing the sealing resin as transparent.

FIG. 24 is a plan view of a semiconductor device according to a fourth embodiment of the present disclosure, showing a sealing resin as transparent.

FIG. 25 is a partially enlarged sectional view taken along line XXV-XXV of FIG. 24.

FIG. 26 is a partially enlarged sectional view taken along line XXVI-XXVI of FIG. 24.

FIG. 27 is a partially enlarged plan view of a semiconductor device according to a fifth embodiment of the present disclosure, showing a part around a first element and showing a sealing resin as transparent.

FIG. 28 is a sectional view taken along line XXVIII-XXVIII of FIG. 27.

FIG. 29 is a partially enlarged plan view of the semiconductor device of FIG. 27, showing a part around a second element and showing the sealing resin as transparent.

FIG. 30 is a sectional view taken along line XXX-XXX of FIG. 29.

FIG. 31 is a partially enlarged plan view of a first variation of the semiconductor device of FIG. 27, showing a sealing resin as transparent.

FIG. 32 is a partially enlarged plan view of a second variation of the semiconductor device of FIG. 27, showing a sealing resin as transparent.

FIG. 33 is a partially enlarged plan view of a semiconductor device according to a sixth embodiment of the present disclosure, showing a part around a first element and showing a sealing resin as transparent.

FIG. 34 is a sectional view taken along line XXXIV-XXXIV of FIG. 33.

FIG. 35 is a sectional view taken along line XXXV-XXXV of FIG. 33.

FIG. 36 is a partially enlarged plan view of a variation of the semiconductor device of FIG. 33, showing a sealing resin as transparent.

FIG. 37 is a partially enlarged plan view of a semiconductor device according to a seventh embodiment of the present disclosure, showing a part around a first element and showing a sealing resin as transparent.

FIG. 38 is a sectional view taken along line XXXVIII-XXXVIII of FIG. 37.

FIG. 39 is a partially enlarged plan view of a semiconductor device according to an eighth embodiment of the present disclosure, showing a part around a first element and showing a sealing resin as transparent.

FIG. 40 is a sectional view taken along line XL-XL of FIG. 39.

### DETAILED DESCRIPTION OF EMBODIMENTS

The following describes preferred embodiments of the present disclosure with reference to the drawings.

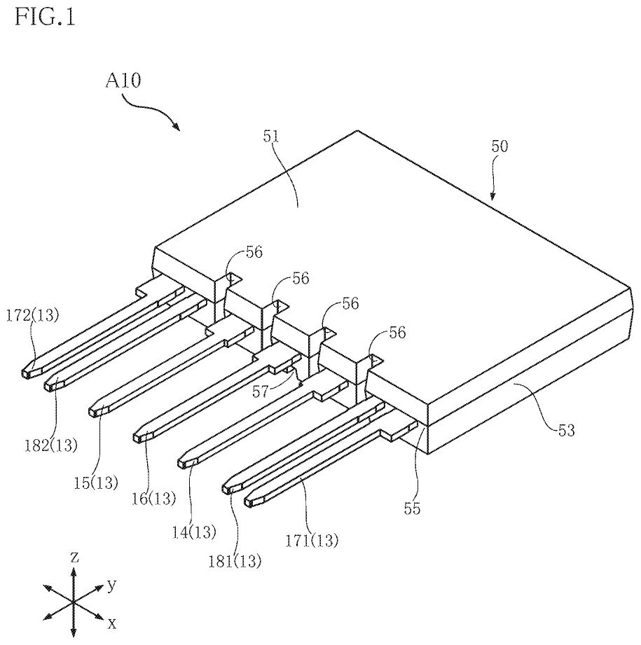

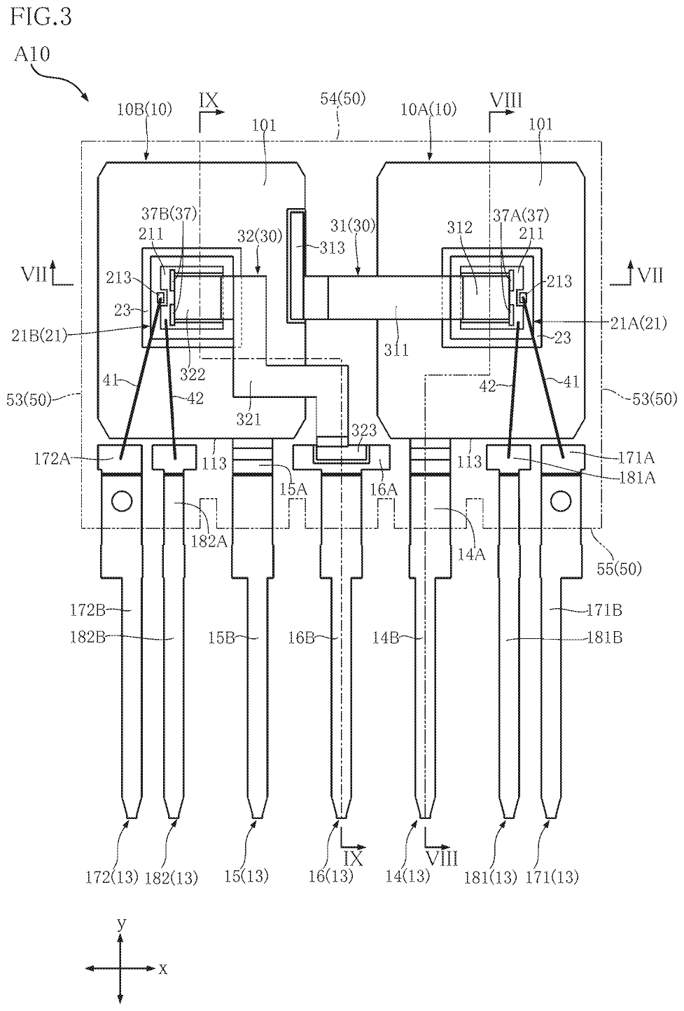

With reference to FIGS. 1 to 15, the following describes a semiconductor device A10 according to a first embodiment of the present disclosure. The semiconductor device A10 includes a support member 10, a plurality of terminal leads 13, a semiconductor element 21, a conductive member 30, a pair of gate wires 41, a pair of detection wires 42 and a sealing resin 50. For the convenience of description, FIG. 3 shows the sealing resin 50 as transparent with imaginary lines (dash-double dot lines). FIG. 3 shows a line VIII-VIII and a line IX-IX with dash-dot lines.

For the convenience of description of the semiconductor device A10, the thickness direction of the semiconductor element 21 is referred to as a “thickness direction z”. A direction orthogonal to the thickness direction z is referred to as a “first direction x”. The direction orthogonal to both the thickness direction z and the first direction x is referred to as a “second direction y”.

In the semiconductor device A10, the terminal leads 13 includes a first input terminal 14 and a second input terminal 16 across which a direct-current source voltage is applied. The semiconductor element 21 converts the direct-current source voltage into alternating-current power. The terminal leads 13 also include an output terminal 15 from which the alternating-current power is outputted and supplied to a target, such as a motor. The semiconductor device A10 is used for a power conversion circuit, such as an inverter.

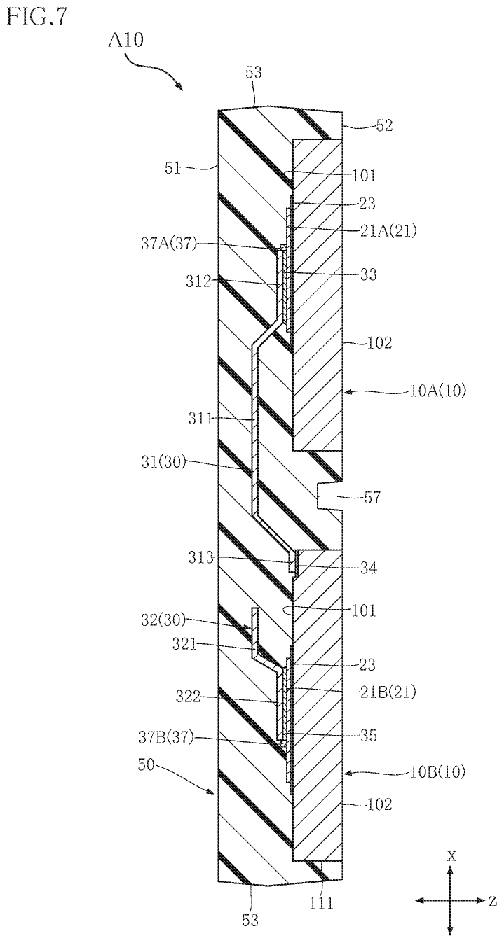

The support member 10 and the terminal leads 13 are made from a single lead frame. The lead frame is made of copper (Cu) or a copper alloy. Thus, the composition of the support member 10 and the terminal leads 13 contain copper (in other words, they contain copper). The support member 10 is electrically conductive. In the semiconductor device A10, the support member 10 includes a first die pad 10A and a second die pad 10B spaced apart from each other in the first direction x as shown in FIGS. 3 and 7. The support member 10 has an obverse surface 101 and a reverse surface 102. The obverse surface 101 faces in the thickness direction z. The obverse surface 101 is covered with the sealing resin 50. The semiconductor element 21 is mounted on the obverse surface 101. The reverse surface 102 faces away from the semiconductor element 21 in the thickness direction z. The reverse surface 102 is exposed from the sealing resin 50. The reverse surface 102 may be plated with tin (Sn), for example.

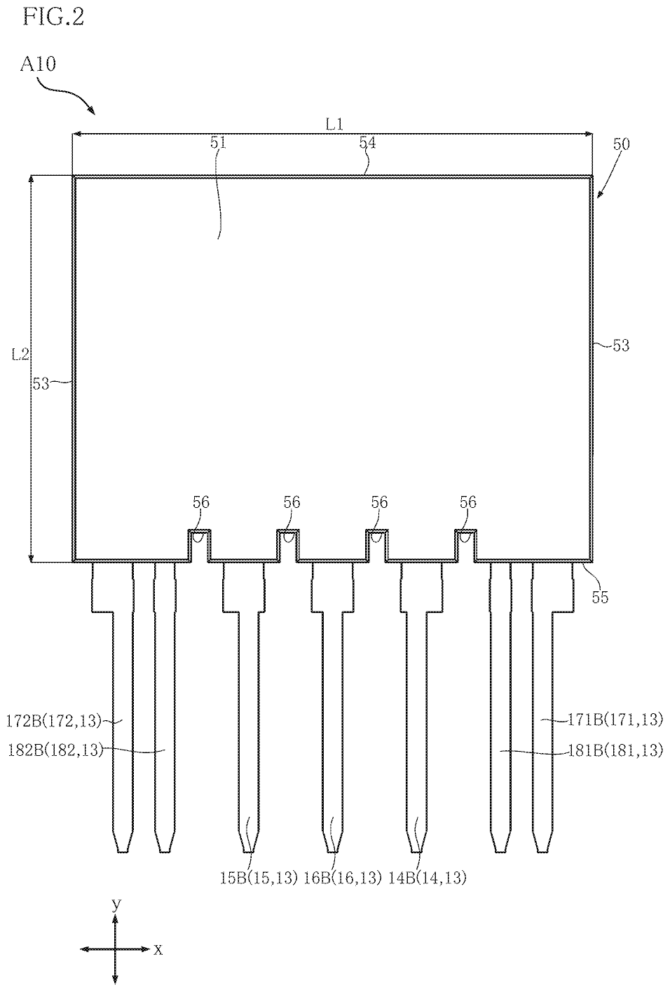

As shown in FIGS. 3 and 7 to 9, the sealing resin 50 covers the semiconductor element 21, the conductive member 30, and a part of the support member 10 (a part of the first die pad 10A and a part of the second die pad 10B). The sealing resin 50 also covers a part of each terminal lead 13. The sealing resin 50 is electrically insulating. The sealing resin 50 may be made of a material containing black epoxy resin. As shown in FIG. 2, the sealing resin 50 has a length L1 in the first direction x and a length L2 in the second direction y, where L1 is greater than L2. The sealing resin 50 has a top surface 51, a bottom surface 52, a pair of first side surfaces 53, a second side surface 54, a third side surface 55, a plurality of recesses 56 and a trench 57.

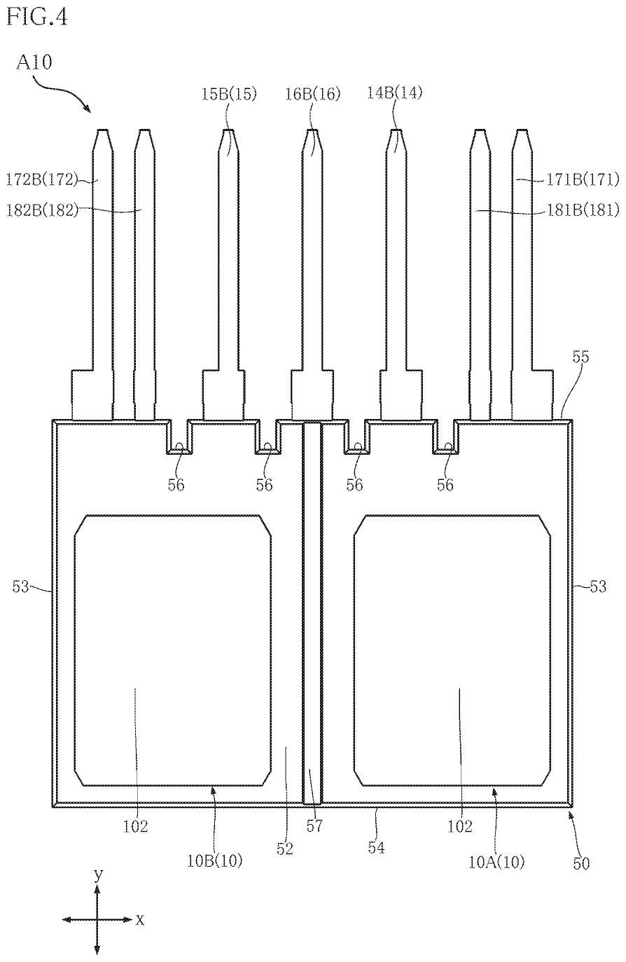

As shown in FIGS. 7 to 9, the top surface 51 faces the same side as the obverse surface 101 of the first die pad 10A and the second die pad 10B in the thickness direction z. As shown in FIGS. 7 to 9, the bottom surface 52 faces away from the top surface 51 in the thickness direction z. As shown in FIG. 4, the reverse surface 102 of the first die pad 10A and the reverse surface 102 of the second die pad 10B are exposed on the bottom surface 52.

As shown in FIGS. 2, 4 and 5, the first side surfaces 53 are spaced apart from each other in the first direction x. Each first side surface 53 faces in the first direction x and extends in the second direction y. Each first side surface 53 is connected to the top surface 51 and the bottom surface 52.

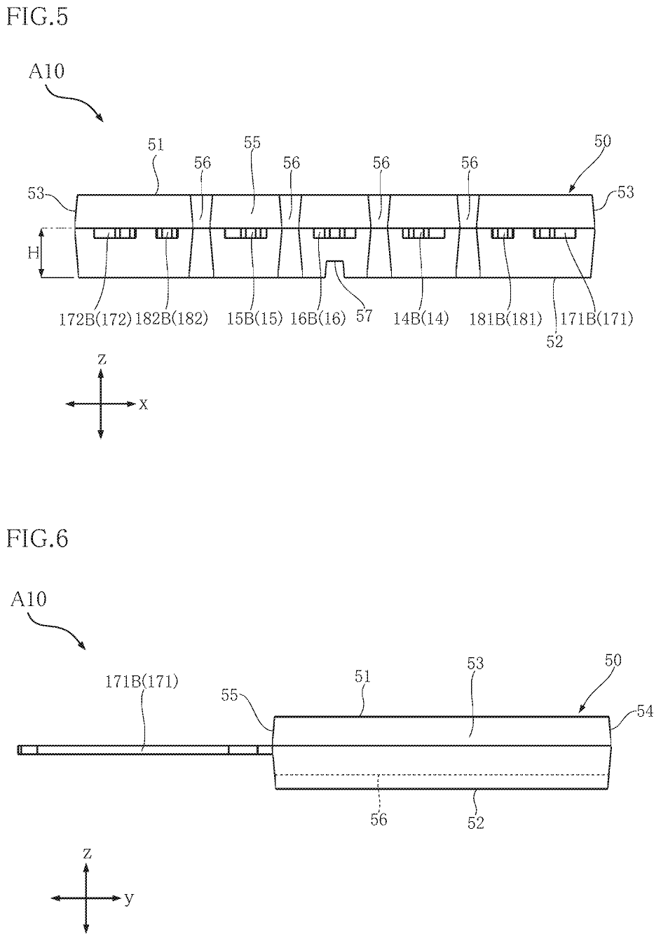

As shown in FIGS. 2, 4 and 6, the second side surface 54 and the third side surface 55 are spaced apart from the each other in the second direction y. The second side surface 54 and the third side surface 55 face away from each other in the second direction y and extend in the first direction x. The second side surface 54 and the third side surface 55 are connected to the top surface 51 and the bottom surface 52. As shown in FIG. 5, the terminal leads 13 are exposed from the third side surface 55.

As shown in FIGS. 2, 4 and 5, the recesses 56 are recessed from the third side surface 55 in the second direction y and extend from the top surface 51 to the bottom surface 52 in the thickness direction z. The recesses 56 are located along the first direction x, including one located between the first input terminal 14 and a first detection terminal 181, one located between the first input terminal 14 and the second input terminal 16, one located between the output terminal 15 and the second input terminal 16, and one located between the output terminal 15 and a second detection terminal 182.

As shown in FIGS. 4, 5, 7 and 9, the trench 57 is recessed from the bottom surface 52 in the thickness direction z and extends in the second direction y. The opposite ends of the trench 57 in the second direction y are connected to the second side surface 54 and the third side surface 55. The trench 57 is located between the first die pad 10A and the second die pad 10B. As viewed in the thickness direction z, the trench 57 separates the reverse surface 102 of the first die pad 10A and the reverse surface 102 of the second die pad 10B.

As shown in FIG. 10, the second die pad 10B has a first seating surface 103 and a first upstanding surface 104. The first seating surface 103 faces the same side as the obverse surface 101 in the thickness direction z and is located between the obverse surface 101 and the reverse surface 102 in the thickness direction z. The first upstanding surface 104 faces in a direction orthogonal to the thickness direction z and is connected to the first seating surface 103 and the obverse surface 101. The first seating surface 103 and the first upstanding surface 104 form a step in the second die pad 10B.

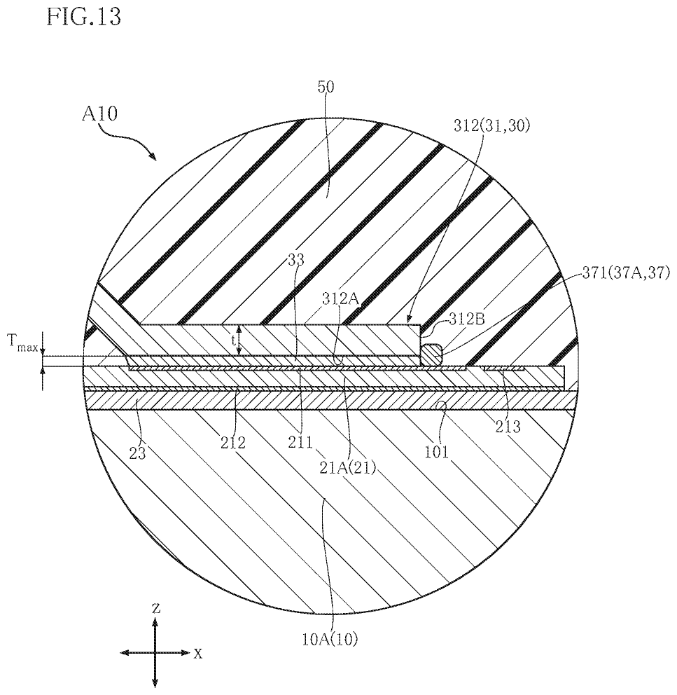

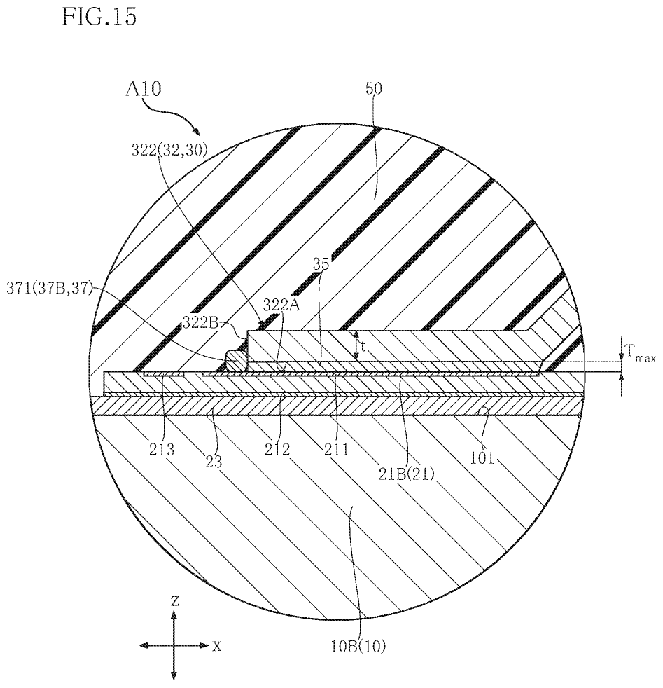

As shown in FIGS. 3 and 7, the semiconductor element 21 is mounted on the support member 10. In the semiconductor device A10, the semiconductor element 21 includes a first element 21A and a second element 21B. The first element 21A is mounted on the obverse surface 101 of the first die pad 10A. The second element 21B is mounted on the obverse surface 101 of the second die pad 10B. The semiconductor element 21 may be a metal-oxide-semiconductor field-effect transistors (MOSFET), for example. In another example, the semiconductor element 21 may be another switching element, such as an insulated gate bipolar transistor (IGBT), or a diode. In the following description of the semiconductor device A10, the semiconductor element 21 is an n-channel vertical MOSFET. The semiconductor element 21 includes a compound semiconductor substrate. The composition of the compound semiconductor substrate contains silicon carbide (SiC). As shown in FIGS. 13 and 15, the semiconductor element 21 includes a first electrode 211, a second electrode 212 and a gate electrode 213.

As shown in FIGS. 13 and 15, the first electrode 211 is located on the side opposite the second electrode 212 in the thickness direction z. The first electrode 211 is an electrode through which a current corresponding to the power converted by the semiconductor element 21 flows. In other words, the first electrode 211 is the source electrode of the semiconductor element 21. The first electrode 211 includes a plurality of metal plating layers. The first electrode 211 includes a nickel (Ni) plating layer and a gold (Au) plating layer on the nickel plating layer. In another example, the first electrode 211 may include a nickel plating layer, a palladium (Pd) plating layer on the nickel plating layer, and a gold plating layer on the palladium plating layer.

As shown in FIGS. 13 and 15, the second electrode 212 faces the obverse surface 101 of the support member 10. The second electrode 212 is an electrode through which a current corresponding to the power before the conversion by the semiconductor element 21 flows. In other words, the second electrode 212 is the drain electrode of the semiconductor element 21.

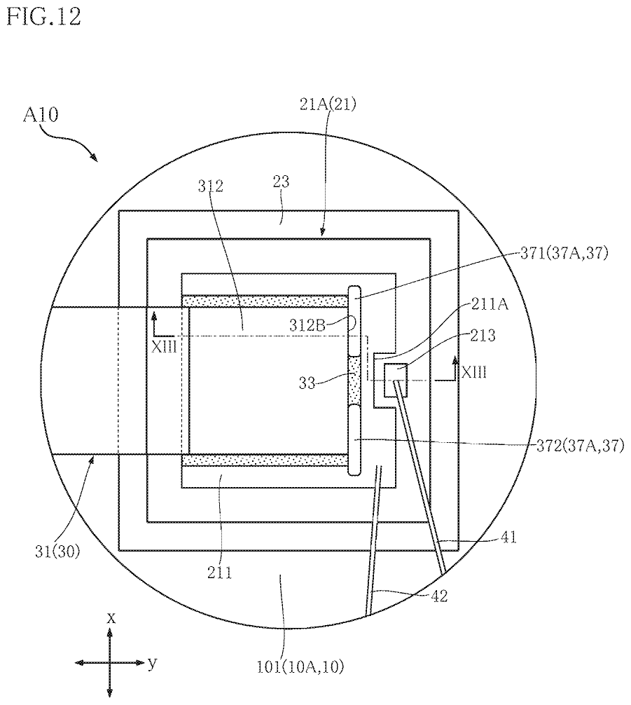

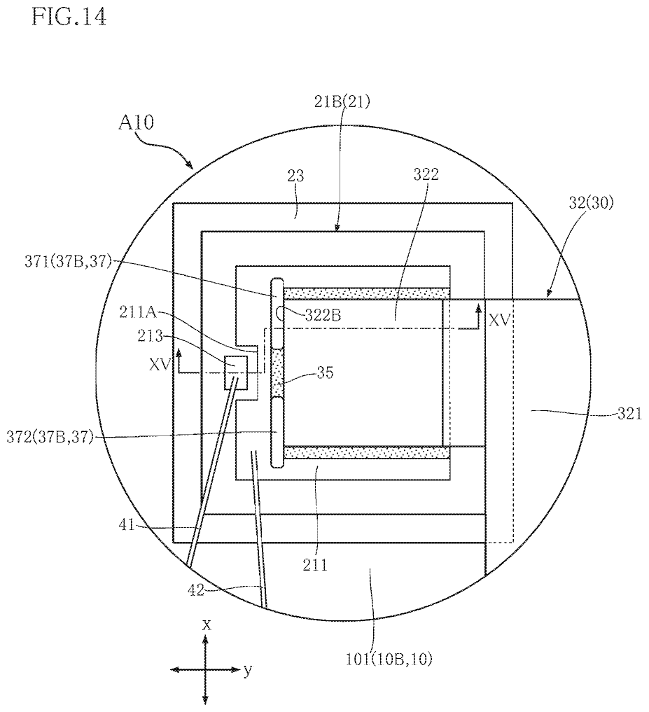

As shown in FIGS. 13 and 15, the gate electrode 213 is located on the same side as the first electrode 211 in the thickness direction z. The gate voltage for driving the semiconductor element 21 is applied to the gate electrode 213. As shown in FIGS. 12 and 14, the gate electrode 213 has a smaller area than the first electrode 211 as viewed in thickness direction z.

As shown in FIGS. 12 and 14, the first electrode 211 includes a first recess 211A that is recessed in the first direction x. As viewed in the thickness direction z, the gate electrode 213 overlaps with the first recess 211A.

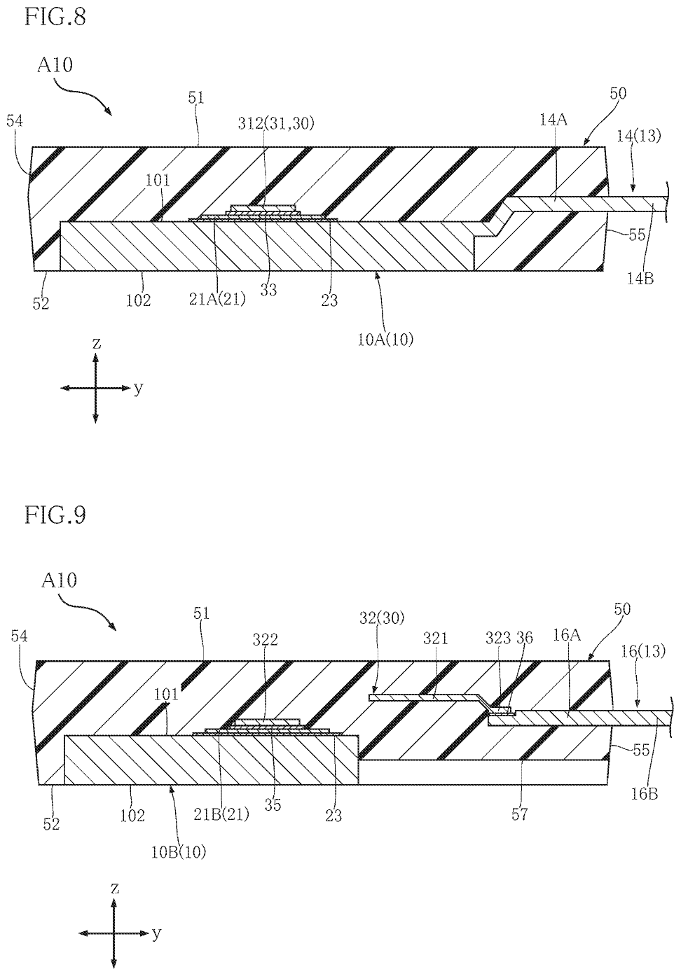

As shown in FIGS. 8, 10 and 11, a die-bonding layer 23 is interposed between the obverse surface 101 of each of the first die pad 10A and the second die pad 10B and the first electrode 211 of the semiconductor element 21 (the first element 21A and the second element 21B). The die-bonding layer 23 is electrically conductive. The die-bonding layer 23 may be made of solder, for example. In another example, the die-bonding layer 23 may be made of sintered metal. The die-bonding layer 23 bonds the obverse surface 101 of the first die pad 10A and the second electrode 212 of the first element 21A together. This electrically connects the second electrode 212 of the first element 21A to the first die pad 10A. The die-bonding layer 23 also bonds the obverse surface 101 of the second die pad 10B and the second electrode 212 of the second element 21B together. This electrically connects the second electrode 212 of the second element 21B to the second die pad 10B.

As shown in FIG. 3, the terminal leads 13 are located on one side of the support member 10 in the second direction y. The terminal leads 13 are electrically connected to the semiconductor element 21. The terminal leads 13 are arranged along the first direction x. The terminal leads 13 include the first input terminal 14, the output terminal 15, the second input terminal 16, a first gate terminal 171, a second gate terminal 172, the first detection terminal 181 and the second detection terminal 182.

As shown in FIG. 3, the first input terminal 14 includes a part extending in the second direction y and is connected to the first die pad 10A. Hence, the first input terminal 14 is electrically connected to the second electrode 212 of the first element 21A via the first die pad 10A. The first input terminal 14 is a P-terminal (positive electrode) to which the direct-current source voltage to be converted is applied . The first input terminal 14 includes a covered part 14A and an exposed part 14B. As shown in FIG. 7, the covered part 14A is connected to the first die pad 10A and covered with the sealing resin 50. The covered part 14A is bent as viewed in the first direction x. As shown in FIGS. 2 to 5, the exposed part 14B is connected to the covered part 14A and exposed from the third side surface 55 of the sealing resin 50. The exposed part 14B extends away from the first die pad 10A in the second direction y. The surface of the exposed part 14B may be plated with tin, for example.

As shown in FIG. 3, the output terminal 15 includes a part extending in the second direction y and is connected to the second die pad 10B. Hence, the output terminal 15 is electrically connected to the second electrode 212 of the second element 21B via the second die pad 10B. The output terminal 15 outputs the alternating-current power converted by the semiconductor element 21. The output terminal 15 includes a covered part 15A and an exposed part 15B. The covered part 15A is connected to the second die pad 10B and covered with the sealing resin 50. The covered part 15A is bent as viewed in the first direction x, similarly to the covered part 14A of the first input terminal 14. As shown in FIGS. 2 to 5, the exposed part 15B is connected to the covered part 15A and exposed from the third side surface 55 of the sealing resin 50. The exposed part 15B extends away from the second die pad 10B in the second direction y. The surface of the exposed part 14B may be plated with tin, for example.

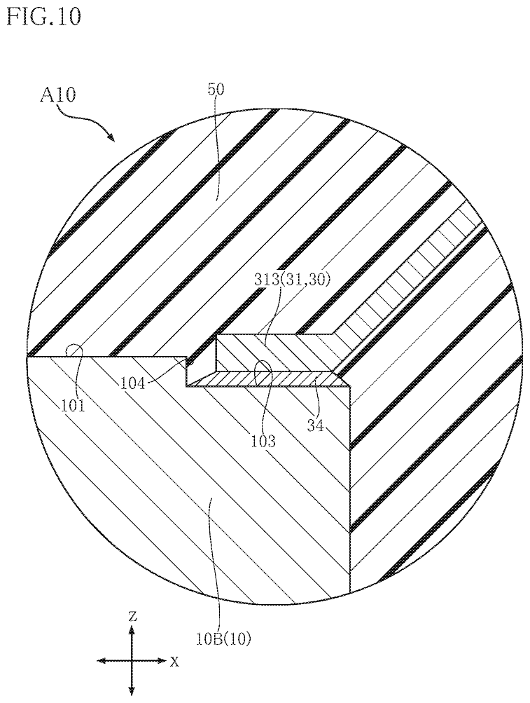

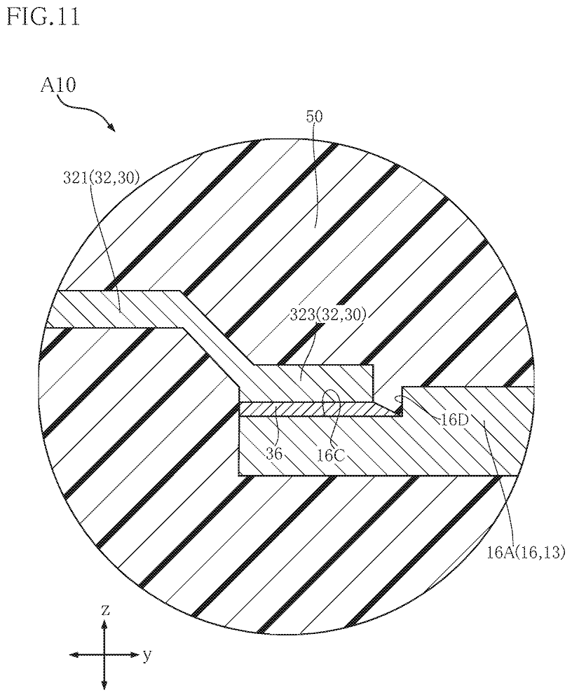

As shown in FIG. 3, the second input terminal 16 is spaced apart from the first die pad 10A and the second die pad 10B in the second direction y, and located between the first input terminal 14 and the output terminal 15 in the first direction x. The second input terminal 16 extends in the second direction y. The second input terminal 16 is electrically connected to the first electrode 211 of the second element 21B. The second input terminal 16 is an N-terminal (negative electrode) to which the direct-current source voltage to be converted is applied. The second input terminal 16 includes a covered part 16A and an exposed part 16B. As shown in FIG. 9, the covered part 16A is covered with the sealing resin 50. As shown in FIGS. 2 to 5, the exposed part 16B is connected to the covered part 16A and exposed from the third side surface 55 of the sealing resin 50. The exposed part 16B extends away from the first die pad 10A and the second die pad 10B in the second direction y. The surface of the exposed part 16B may be plated with tin, for example.

As shown in FIG. 11, the covered part 16A of the second input terminal 16 includes a second seating surface 16C and a second upstanding surface 16D. The second seating surface 16C faces the same side as the obverse surface 101 of the first die pad 10A and the second die pad 10B and is located below the upper surface of the covered part 16A (the surface facing upward in FIG. 11) as seen in FIG. 11. The second upstanding surface 16D faces in a direction orthogonal to the thickness direction z and is connected to the second seating surface 16C and the upper surface of the covered part 16A. The second seating surface 16C and the second upstanding surface 16D form a step in the covered part 16A of the second input terminal 16.

As shown in FIG. 3, the first gate terminal 171 is spaced apart from the first die pad 10A in the second direction y and located on one side in the first direction x. As shown in FIG. 3, the second gate terminal 172 is spaced apart from the second die pad 10B in the second direction y and located on the other side in the first direction x. The first gate terminal 171 is electrically connected to the gate electrode 213 of the first element 21A. The gate voltage for driving the first element 21A is applied to the first gate terminal 171. The second gate terminal 172 is electrically connected to the gate electrode 213 of the second element 21B. The gate voltage for driving the second element 21B is applied to the second gate terminal 172.

As shown in Fig. FIG. 3, the first gate terminal 171 includes a covered part 171A and an exposed part 171B. The covered part 171A is covered with the sealing resin 50. As shown in FIGS. 2 to 5, the exposed part 171B is connected to the covered part 171A and exposed from the third side surface 55 of the sealing resin 50. The exposed part 171B extends away from the first die pad 10A in the second direction y. The surface of the exposed part 171B may be plated with tin, for example.

As shown in Fig. FIG. 3, the second gate terminal 172 includes a covered part 172A and an exposed part 172B. The covered part 172A is covered with the sealing resin 50. As shown in FIGS. 2 to 5, the exposed part 172B is connected to the covered part 172A and exposed from the sealing resin 50. The exposed part 172B extends away from the second die pad 10B in the second direction y. The surface of the exposed part 172B may be plated with tin, for example.

As shown in FIG. 3, the first detection terminal 181 is spaced apart from the first die pad 10A in the second direction y and located between the first input terminal 14 and the first gate terminal 171 in the first direction x. As shown in FIG. 3, the second detection terminal 182 is spaced apart from the second die pad 10B in the second direction y and located between the output terminal 15 and the second gate terminal 172 in the first direction x. The first detection terminal 181 is electrically connected to the second electrode 212 of the first element 21A. The voltage at the first detection terminal 181 corresponds to the current flowing through the second electrode 212 of the first element 21A. The second detection terminal 182 is electrically connected to the second electrode 212 of the second element 21B. The voltage at the second detection terminal 182 corresponds to the current flowing through the second electrode 212 of the second element 21B.

As shown in Fig. FIG. 3, the first detection terminal 181 includes a covered part 181A and an exposed part 181B. The covered part 181A is covered with the sealing resin 50. As shown in FIGS. 2 to 5, the exposed part 181B is connected to the covered part 181A and exposed from the third side surface 55 of the sealing resin 50. The exposed part 181B extends away from the first die pad 10A in the second direction y. The surface of the exposed part 181B may be plated with tin, for example.

As shown in Fig. FIG. 3, the second detection terminal 182 includes a covered part 182A and an exposed part 182B. The covered part 182A is covered with the sealing resin 50. As shown in FIGS. 2 to 5, the exposed part 182B is connected to the covered part 182A and exposed from the third side surface 55 of the sealing resin 50. The exposed part 182B extends away from the second die pad 10B in the second direction y. The surface of the exposed part 182B may be plated with tin, for example.

As shown in FIG. 5, in the semiconductor device A10, the exposed part 14B of the first input terminal 14, the exposed part 15B of the output terminal 15 and the exposed part 16B of the second input terminal 16 all have the same height H. In addition, these exposed parts all have the same thickness. Thus, as viewed in the first direction x, at least a part of the second input terminal 16 (the exposed part 16B) overlaps with the first input terminal 14 and the output terminal 15 (see FIG. 6).

The conductive member 30 forms conduction paths in the semiconductor device A10, together with the support member 10 and the terminal leads 13. The composition of the conductive member 30 contains copper. The conductive member 30 is a metal clip. As shown in FIGS. 3 and 7, in the semiconductor device A10, the conductive member 30 includes a first conductive member 31 and a second conductive member 32.

As shown in FIG. 3, the first conductive member 31 is bonded to the first electrode 211 of the first element 21A and the second die pad 10B. This electrically connects the first electrode 211 of the first element 21A to the second die pad 10B and thus to the second electrode 212 of the second element 21B. The first conductive member 31 includes a main part 311, a first bonding part 312 and a second bonding part 313. As shown in FIG. 7, the first die pad 10A is located on the side opposite the first bonding part 312 with respect to the first element 21A in the thickness direction z.

The main part 311 is the body of the first conductive member 31. As shown in FIG. 3, the main part 311 extends in the first direction x. As shown in FIG. 7, the main part 311 extends across the gap between the first die pad 10A and the second die pad 10B.

As shown in FIGS. 12 and 13, the first bonding part 312 faces the first electrode 211 of the first element 21A. The first bonding part 312 is connected to the main part 311. The first bonding part 312 has a bonding surface 312A and an end surface 312B. The bonding surface 312A faces the first electrode 211 of the first element 21A. The end surface 312B faces in the first direction x. The end surface 312B is located between the bonding surface 312A and the gate electrode 213 of the first element 21A in the first direction x. As shown in FIG. 12, a part of the first electrode 211 of the first element 21A is located between the gate electrode 213 of the first element 21A and the first bonding part 312 as viewed in the thickness direction z.

As shown in FIG. 10, the second bonding part 313 is bonded to the first seating surface 103 of the second die pad 10B. The second bonding part 313 extends in the second direction y. At least a part of the second bonding part 313 is received within a region of the second die pad 10B defined by the first seating surface 103 and the first upstanding surface 104. The second bonding part 313 is connected to the main part 311. The second bonding part 313 is located opposite the first bonding part 312 with the main part 311 in between.

As shown in FIGS. 12 and 13, the semiconductor device A10 further includes a first bonding layer 33. In FIG. 12, the first bonding layer 33 is shaded with dots. The first bonding layer 33 is interposed between the first electrode 211 of the first element 21A and the first bonding part 312. The first bonding layer 33 bonds the first electrode 211 of the first element 21A and the first bonding part 312 together. The first bonding layer 33 is electrically conductive. The first bonding layer 33 is made of solder.

The first bonding part 312 has a thickness t that is at least 0.1 mm and at most twice the maximum thickness Tₘₐₓ of the first bonding layer 33. The maximum thickness Tₘₐₓ of the first bonding layer 33 is greater than the thickness of the first element 21A.

As shown in FIGS. 7 and 10, the semiconductor device A10 further includes a second bonding layer 34. The second bonding layer 34 is interposed between the first seating surface 103 of the second die pad 10B and the second bonding part 313. The second bonding layer 34 bonds the second die pad 10B and the second bonding part 313 together. The second bonding layer 34 is electrically conductive. The second bonding layer 34 is made of solder.

As shown in FIG. 3, the second conductive member 32 is bonded to the first electrode 211 of the second element 21B and the covered part 16A of the second input terminal 16. This electrically connects the first electrode 211 of the second element 21B to the second input terminal 16. The second conductive member 32 includes a main part 321, a third bonding part 322 and a fourth bonding part 323. As shown in FIG. 7, the second die pad 10B is located on the side opposite the third bonding part 322 with respect to the second element 21B in the thickness direction z.

The main part 321 is the body of the second conductive member 32. As shown in FIG. 3, the main part 321 is bent into a hook-like shape as viewed in the thickness direction z. The main part 311 overlaps with the obverse surface 101 of the second die pad 10B as viewed in the thickness direction z.

As shown in FIGS. 14 and 15, the third bonding part 322 faces the first electrode 211 of the second element 21B. The third bonding part 322 is connected to the main part 321. The third bonding part 322 has a bonding surface 322A and an end surface 322B. The bonding surface 322A faces the first electrode 211 of the second element 21B. The end surface 322B faces in the first direction x. The end surface 322B is located between the bonding surface 322A and the gate electrode 213 of the second element 21B in the first direction x. As shown in FIG. 14, a part of the first electrode 211 of the second element 21B is located between the gate electrode 213 of the second element 21B and the third bonding part 322 as viewed in the thickness direction z.

As shown in FIG. 11, the fourth bonding part 323 is bonded to the second seating surface 16C of the second input terminal 16. The fourth bonding part 323 extends in the first direction x. At least a part of the fourth bonding part 323 is received within a region of the second input terminal 16 defined by the second seating surface 16C and the second upstanding surface 16D. The fourth bonding part 323 is connected to the main part 321. The fourth bonding part 323 is located opposite the third bonding part 322 with the main part 321 in between.

As shown in FIGS. 14 and 15, the semiconductor device A10 further includes a third bonding layer 35. In FIG. 14, the third bonding layer 35 is shaded with dots. The third bonding layer 35 is interposed between the first electrode 211 of the second element 21B and the third bonding part 322. The third bonding layer 35 bonds the first electrode 211 of the second element 21B and the third bonding part 322 together. The third bonding layer 35 is electrically conductive. The third bonding layer 35 is made of solder.

The third bonding part 322 has a thickness t that is at least 0.1 mm and at most twice the maximum thickness Tₘₐₓ of the third bonding layer 35. The maximum thickness Tₘₐₓ of the third bonding layer 35 is greater than the thickness of the second element 21B.

As shown in FIGS. 9 and 11, the semiconductor device A10 further includes a fourth bonding layer 36. The fourth bonding layer 36 is interposed between the second seating surface 16C of the second input terminal 16 and the fourth bonding part 323. The fourth bonding layer 36 bonds the covered part 16A of the second input terminal 16 and the fourth bonding part 323 together. The fourth bonding layer 36 is electrically conductive. The fourth bonding layer 36 is made of solder.

As shown in FIGS. 12 to 15, the semiconductor device A10 further includes a regulator 37. The regulator 37 contains a metallic element. The metallic element is aluminum (Al). In the semiconductor device A10, the regulator 37 is formed during the fabrication of the semiconductor element 21 by bonding a piece of metal to the first electrode 211 of the semiconductor element 21. The metal piece can be formed by wire bonding. The regulator 37 extends in the second direction y. In the semiconductor device A10, the regulator 37 includes a first regulator 37A bonded to the first electrode 211 of the first element 21A and a second regulator 37B bonded to the first electrode 211 of the second element 21B.

As shown in FIG. 13, the first regulator 37A faces the first bonding layer 33 in the first direction x. The first regulator 37A is in contact with the first bonding layer 33 and the end surface 312B of the first bonding part 312 of the first conductive member 31. As shown in FIG. 12, the first regulator 37A includes a first part 371 and a second part 372 spaced apart from each other in the second direction y. A part of the first bonding layer 33 is located between the first part 371 and the second part 372.

As shown in FIG. 15, the second regulator 37B faces the third bonding layer 35 in the first direction x. The second regulator 37B is in contact with the third bonding layer 35 and the end surface 322B of the third bonding part 322 of the second conductive member 32. As shown in FIG. 14, the second regulator 37B includes a first part 371 and a second part 372 spaced apart from each other in the second direction y. A part of the third bonding layer 35 is located between the first part 371 and the second part 372.

As shown in FIG. 3, one of the gate wires 41 is bonded to the gate electrode 213 of the first element 21A and the covered part 171A of the first gate terminal 171, and the other is bonded to the gate electrode 213 of the second element 21B and the covered part 172A of the second gate terminal 172. With these wires, the first gate terminal 171 is electrically connected to the gate electrode 213 of the first element 21A, and the second gate terminal 172 is electrically connected to the gate electrode 213 of the second element 21B. The composition of the pair of gate wires 41 contains gold. In another example, the composition of the pair of gate wires 41 may contain copper or aluminum.

As shown in FIG. 3, one of the detection wires 42 is bonded to the first electrode 211 of the first element 21A and the covered part 181A of the first detection terminal 181, and the other is bonded to the first electrode 211 of the second element 21B and the covered part 182A of the second detection terminal 182. With these wires, the first detection terminal 181 is electrically connected to the first electrode 211 of the first element 21A, and the second detection terminal 182 is electrically connected to the first electrode 211 of the second element 21B. The composition of the pair of detection wires 42 contains gold. In another example, the composition of the pair of detection wires 42 may contain copper or aluminum.

Next, advantages of the semiconductor device A10 will be described.

The semiconductor device A10 includes the semiconductor element 21 (the first element 21A) including the first electrode 211, the conductive member 30 (the first conductive member 31) including the first bonding part 312 facing the semiconductor element 21, and the bonding layer (the first bonding layer 33) interposed between the first electrode 211 and the first bonding part 312. The semiconductor device A10 further includes the regulator 37 (the first regulator 37A) bonded to the first electrode 211. The regulator 37 faces the first bonding layer 33 in a direction orthogonal to the thickness direction z. With this configuration, in the process of bonding the first bonding part 312 to the first electrode 211 of the semiconductor element 21 via the first bonding layer 33, the first bonding part 312 comes into contact with the regulator 37. This prevents the first bonding part 312 from deviating relative to the first electrode 211. The semiconductor device A10 can therefore prevent positional misalignment of the conductive member 30 with the electrode (the first electrode 211) of the semiconductor element 21.

The semiconductor element 21 also includes the gate electrode 213 on the same side as the first electrode 211 in the thickness direction z. As viewed in the thickness direction z, a part of the first electrode 211 is located between the gate electrode 213 and the first bonding part 312 of the conductive member 30. This layout results from that the regulator 37 efficiently prevented the deviation of the conductive member 30 relative to the first electrode 211. With this layout, the gate electrode 213 is not covered with the first bonding part 312.

The first bonding part 312 of the conductive member 30 has the end surface 312B facing in the first direction x. The end surface 312B is in contact with the regulator 37. The end surface 312B of the first bonding part 312 comes into contact with the regulator 37 when the first bonding part 312 is forced to move in the first direction x toward the gate electrode 213 of the semiconductor element 21 in the process of bonding the first bonding part 312 to the first electrode 211 of the semiconductor element 21 via the first bonding layer 33. That is, the end surface 312B of the first bonding part 312 can make contact with the regulator 37 more reliably.

The regulator 37 is located between the gate electrode 213 of the semiconductor element 21 and the first bonding part 312 of the conductive member 30 as viewed in the thickness direction z. This arrangement enables the regulator 37 to block the first bonding layer 33 in a molten state from flowing toward the gate electrode 213 in the process of bonding the first bonding part 312 to the first electrode 211 of the semiconductor element 21 via the first bonding layer 33.

The regulator 37 includes the first part 371 and the second part 372 spaced apart from each other in the second direction y. With this configuration, the regulator 37 can be smaller in volume and yet capable of preventing positional misalignment of the conductive member 30 with the first electrode 211 of the semiconductor element 21. In addition, the regulator 37 contains a metallic element. The metallic element is aluminum. Hence, the regulator 37 forms a conduction path between the first electrode 211 of the semiconductor element 21 and the first bonding part 312 of the conductive member 30. Also, the regulator 37 made of such a composition exhibits a higher repellency to the first bonding layer 33 in a molten state. The regulator 37 can therefore more efficiently block the flow of the first bonding layer 33 in a molten state.

The sealing resin 50 has the recesses 56 recessed from the third side surface 55 in the second direction y. This configuration provides the sealing resin 50 with a longer creepage distance between each pair of adjacent terminal leads 13 (except between the first gate terminal 171 and the first detection terminal 181 and between the second gate terminal 172 and the second detection terminal 182). This is effective for improving the dielectric strength of the semiconductor device A10.

The sealing resin 50 includes the trench 57 recessed from the bottom surface 52 and separating the reverse surface 102 of the first die pad 10A and the reverse surface 102 of the second die pad 10B as viewed in the thickness direction z. This configuration provides the sealing resin 50 with a longer creepage distance between the first die pad 10A and the second die pad 10B. This is effective for improving the dielectric strength of the semiconductor device A10. Additionally, this configuration enables the sealing resin 50 to distribute thermal strain in the first direction x. This can reduce the thermal strain concentration on the pair of first side surfaces 53 of the sealing resin 50.

At least one of the terminal leads 13 is connected to the support member 10. With this configuration, the support member 10 is used as an electrically conductive member, without increasing the size of the semiconductor device A10.

The reverse surface 102 of the support member 10 is exposed from the sealing resin 50. This improves the heat dissipation of the semiconductor device A10.

The composition of the conductive member 30 contains copper. This can reduce the electrical resistance of the conductive member 30 than that of a wire containing aluminum in its composition. This is desirable for passing a large current to the semiconductor element 21.

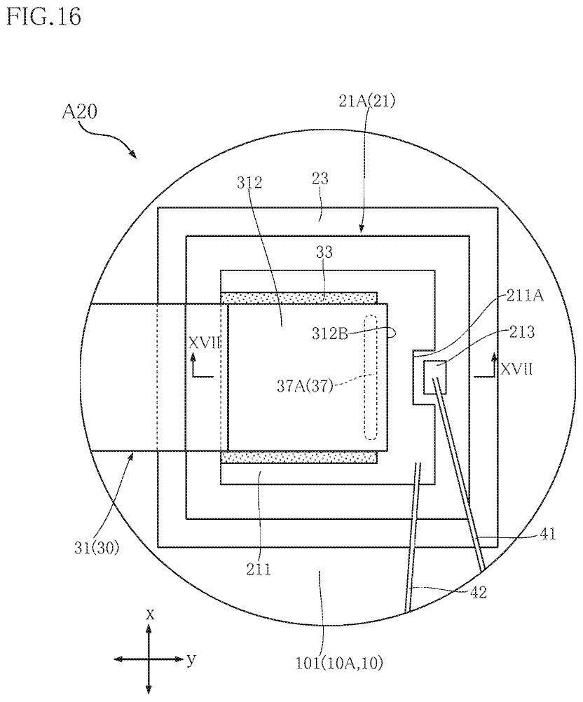

With reference to FIGS. 16 to 19, the following describes a semiconductor device A20 according to a second embodiment of the present disclosure. In these figures, the same or similar elements as those of the semiconductor device A10 described above are denoted by the same reference signs, and redundant descriptions of such elements are omitted. For the convenience of description, FIGS. 16 and 18 show the sealing resin 50 as transparent. FIG. 16 shows the part corresponding to the part of the semiconductor device A10 shown in FIG. 12. FIG. 18 shows the part corresponding to the part of the semiconductor device A10 shown in FIG. 14.

The semiconductor device A20 differs from the semiconductor device A10 in the configuration of the regulator 37.

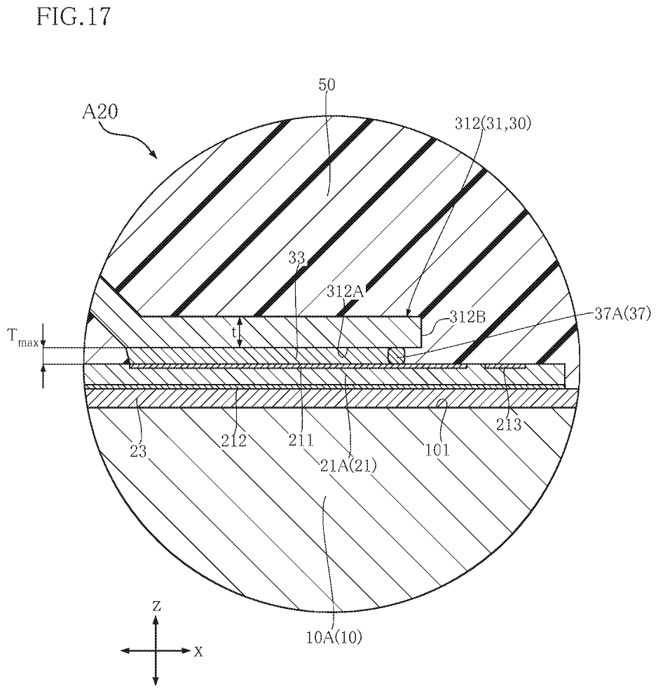

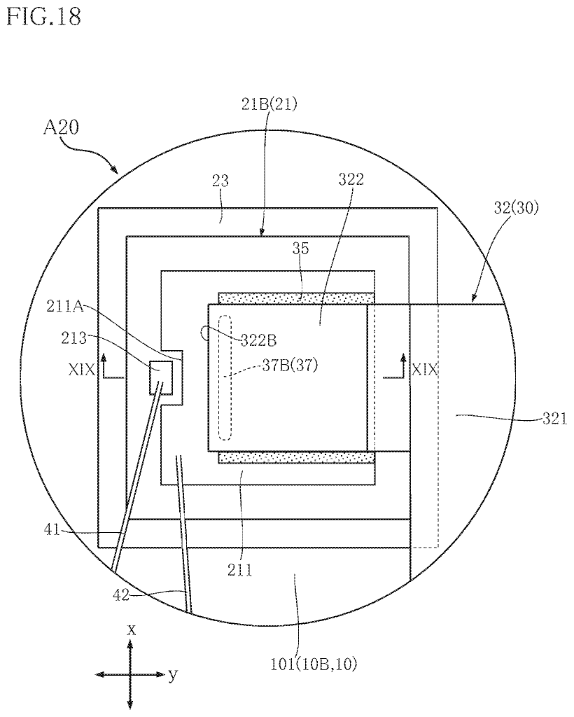

As shown in FIGS. 16 and 17, the first regulator 37A is bonded to the bonding surface 312A of the first bonding part 312 of the first conductive member 31. The first regulator 37A is in contact with the first electrode 211 of the first element 21A. That is, the first regulator 37A is interposed between the first electrode 211 of the first element 21A and the bonding surface 312A along with the first bonding layer 33. In the semiconductor device A20, the first regulator 37A is formed by bonding a piece of metal to the bonding surface 312A using wire bonding.

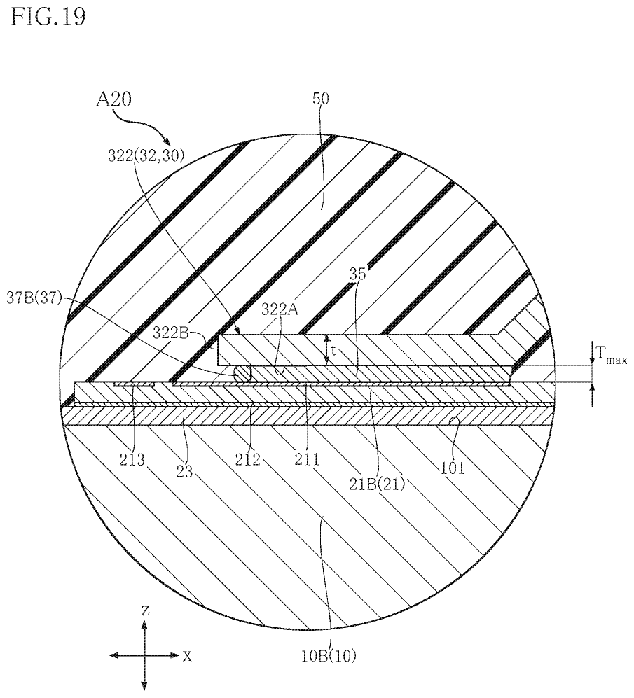

As shown in FIGS. 18 and 19, the second regulator 37B is bonded to the bonding surface 322A of the third bonding part 322 of the second conductive member 32. The second regulator 37B is in contact with the first electrode 211 of the second element 21B. That is, the second regulator 37B is interposed between the first electrode 211 of the second element 21B and the bonding surface 322A along with the third bonding layer 35. In the semiconductor device A20, the second regulator 37B is formed by bonding a piece of metal to the bonding surface 322A using wire bonding.

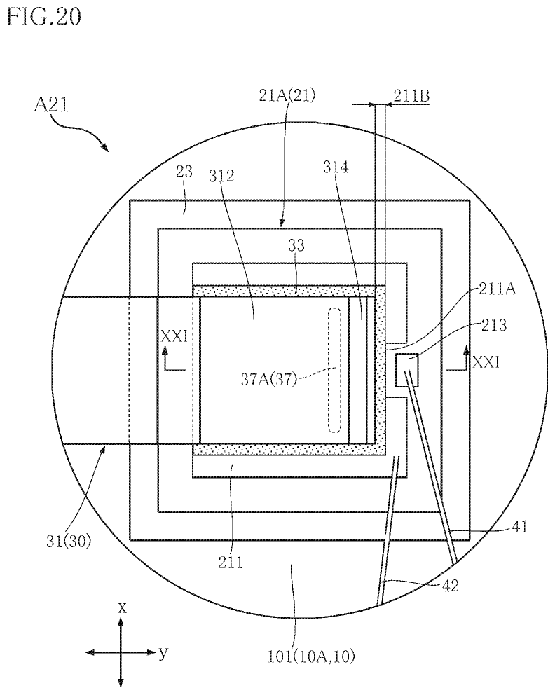

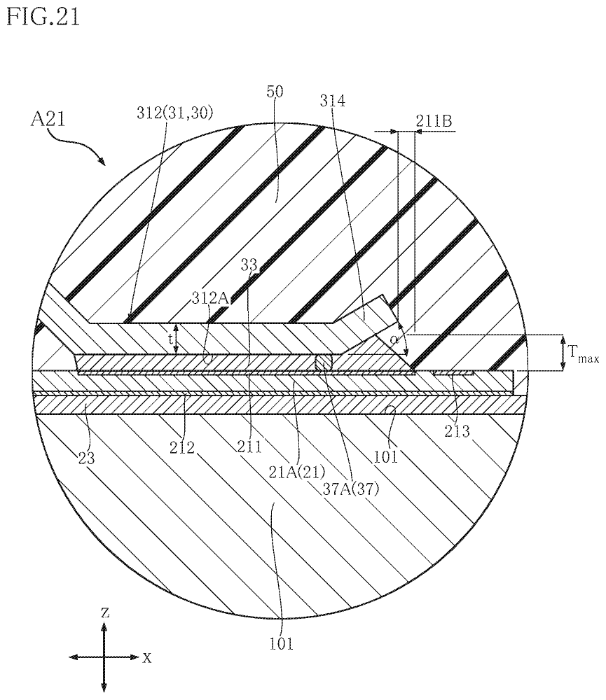

Next, with reference to FIGS. 20 and 21, the following describes a semiconductor device A21 that is a variation of the semiconductor device A20. For the convenience of description, FIG. 20 shows the sealing resin 50 as transparent. The part shown in FIG. 20 corresponds to the part shown in FIG. 16. The configuration of this variation regarding the first electrode 211 of the first element 21A and the first conductive member 31 described below is also applicable to the first electrode 211 of the second element 21B and the second conductive member 32 shown in FIGS. 18 and 19.

As shown in FIGS. 20 and 21, the first conductive member 31 of the semiconductor device A21 includes an end part 314. The end part 314 is connected to the first bonding part 312. The end part 314 is inclined at an inclination angle a relative to the bonding surface 312A of the first bonding part 312 such that the end part 314 is increasingly away from the first electrode 211 of the first element 21A in the thickness direction z with an increase in the distance from the first bonding part 312 in the first direction x. The inclination angle α is at least 30° and at most 60°.

As shown in FIGS. 20 and 21, the first electrode 211 of the first element 21A has an extension part 211B. As viewed in the thickness direction z, the extension part 211B is located on the side opposite the first bonding part 312 with the end part 314 in between.

As shown in Fig. FIG. 21, the first bonding layer 33 is located on the both sides of the first regulator 37A in the first direction x. The first bonding layer 33 is in contact with the extension part 211B of the first electrode 211 of the first element 21A and the end part 314 of the first conductive member 31.

Next, advantages of the semiconductor device A20 will be described.

The semiconductor device A20 includes the semiconductor element 21 (the first element 21A) including the first electrode 211, the conductive member 30 (the first conductive member 31) including the first bonding part 312 facing the semiconductor element 21, and the bonding layer (the first bonding layer 33) interposed between the first electrode 211 and the first bonding part 312. The semiconductor device A20 further includes the regulator 37 (the first regulator 37A) bonded to the first bonding part 312. The regulator 37 faces the first bonding layer 33 in a direction orthogonal to the thickness direction z. With this configuration, in the process of bonding the first bonding part 312 to the first electrode 211 via the first bonding layer 33, the regulator 37 comes into contact with the first bonding layer 33 in a molten state and receives a reaction force from the first bonding layer 33. This prevents the first bonding part 312 from deviating relative to the first electrode 211. The semiconductor device A20 can therefore prevent positional misalignment of the conductive member 30 with the electrode (the first electrode 211) of the semiconductor element 21. Additionally, the semiconductor device A20 has a configuration in common with the semiconductor device A10 and therefore achieves the same advantages as those achieved by the common configuration.

The first bonding part 312 of the conductive member 30 has the bonding surface 312A facing the first electrode 211 of the semiconductor element 21. The regulator 37 is in contact with the bonding surface 312A and bonded to the first electrode 211. That is, the first regulator 37A is sandwiched between the first electrode 211 of the first element 21A and the bonding surface 312A as shown in FIG. 17. With this configuration, the maximum thickness Tₘₐₓ of the first bonding layer 33 is determined by the thickness of the first regulator 37A and thus equal to (or substantially equal to) the thickness of the first regulator 37A. This facilitates controlling the maximum thickness Tₘₐₓ of the first bonding layer 33. Similarly, the second regulator 37B is sandwiched between the first electrode 211 of the second element 21B and the bonding surface 322A of the third bonding part 322 of the second conductive member 32 as shown in FIG. 19. With this configuration, the maximum thickness Tₘₐₓ of the third bonding layer 35 is determined by the thickness of the second regulator 37B and thus equal to (or substantially equal to) the thickness of the second regulator 37B. This facilitates controlling the maximum thickness Tₘₐₓ of the third bonding layer 35.

The semiconductor device A21 is provided with the conductive member 30 having the end part 314 connected to the first bonding part 312. The end part 314 is inclined relative to the bonding surface 312A of the first bonding part 312 such that the end part 314 is increasingly away from the first electrode 211 of the semiconductor element 21 in the thickness direction z with an increase in the distance from the first bonding part 312 in a direction orthogonal to the thickness direction z. In addition, the first electrode 211 has the extension part 211B located, as viewed in the thickness direction z, on the side opposite the first bonding part 312 with the end part 314 in between. With this configuration as shown in FIG. 21, the first bonding layer 33 is placed in contact with the extension part 211B and caused to climb up along the end part 314. As a result, a fillet of a relatively large volume forms in the first bonding layer 33. This serves to improve the strength of bonding between the conductive member 30 and the first electrode 211 and to increase the current that can be passed through to the conductive member 30. Preferably, the inclination angle α of the end part 314 to the bonding surface 312A is at least 30° and at most 60°. The inclination angle α within this range serves to promote the formation of a fillet in the first bonding layer 33 and to reduce the concentration of thermal stress at the interface between the extension part 211B and the first bonding layer 33.

The regulator 37 contains a metallic element. The metallic element is aluminum. Hence, the regulator 37 forms a conduction path between the first electrode 211 of the semiconductor element 21 and the first bonding part 312 of the conductive member 30. In addition, the regulator 37 made of such a composition exhibits a higher repellency to the first bonding layer 33 in a molten state. This increase the reaction force that the regulator 37 receives from the first bonding layer 33 when the regulator 37 comes into contact with the first bonding layer 33 in a molten state. Consequently, the regulator 37 can more efficiently prevent positional misalignment of the conductive member 30.

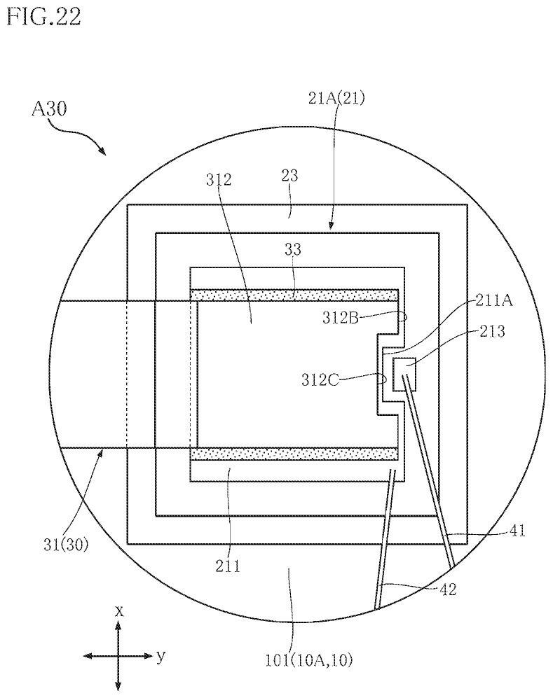

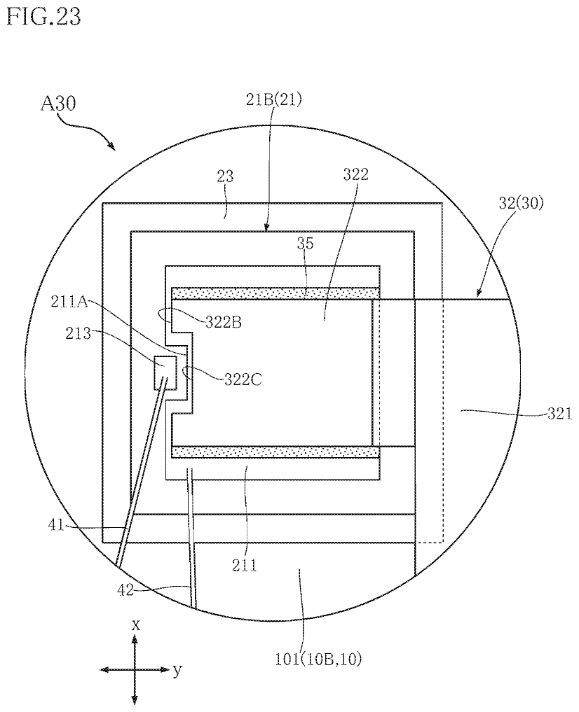

With reference to FIGS. 22 and 23, the following describes a semiconductor device A30 according to a third embodiment of the present disclosure. In these figures, the same or similar elements as those of the semiconductor device A10 described above are denoted by the same reference signs, and redundant descriptions of such elements are omitted. For the convenience of description, FIGS. 22 and 23 show the sealing resin 50 as transparent. FIG. 22 shows the part that correspond to the part of the semiconductor device A10 shown in FIG. 12. FIG. 23 shows the part corresponding to the part of the semiconductor device A10 shown in FIG. 14.

The semiconductor device A30 differs from the semiconductor device A10 in that the regulator 37 is not included. In addition, the configuration of the conductive member 30 is different.

As shown in FIG. 22, the first conductive member 31 includes a first bonding part 312 that is formed with a second recess 312C. The second recess 312C is recessed in the first direction x. As viewed in the thickness direction z, the second recess 312C overlaps with the first recess 211A in the first electrode 211 of the first element 21A. The second recess 312C is larger than the first recess 211A in the first electrode 211 of the first element 21A. As viewed in the thickness direction z, in addition, the gate electrode 213 of the first element 21A overlaps with the first recess 211A in the first electrode 211 of the first element 21A and also with the second recess 312C.

As shown in FIG. 23, the second conductive member 32 includes a third bonding part 322 that is formed with a second recess 322C. The second recess 322C is recessed in the first direction x. As viewed in the thickness direction z, the second recess 322C overlaps with the first recess 211A in the first electrode 211 of the second element 21B. The second recess 322C is larger than the first recess 211A in the first electrode 211 of the second element 21B. The gate electrode 213 of the second element 21B overlaps with the first recess 211A in the first electrode 211 of the second element 21B and also with the second recess 322C.

Next, advantages of the semiconductor device A30 will be described.

The semiconductor device A30 includes the semiconductor element 21 (the first element 21A) including the first electrode 211, the conductive member 30 (the first conductive member 31) including the first bonding part 312 facing the semiconductor element 21, and the bonding layer (the first bonding layer 33) interposed between the first electrode 211 and the first bonding part 312. The first electrode 211 is formed with the first recess 211A recessed in a direction orthogonal to the thickness direction z. The first bonding part 312 is formed with a second recess 312C recessed in a direction orthogonal to the thickness direction z. As viewed in the thickness direction z, the second recess 312C overlaps with the first recess 211A. This configuration increases the possibility that the first recess 211A is not covered by the first bonding part 312 even if the first bonding part 312 deviates relative to the first electrode 211 in the process of bonding the first bonding part 312 to the first electrode 211 via the first bonding layer 33. In this way, the semiconductor device A30 can accommodate positional misalignment of the conductive member 30 with the electrode (the first electrode 211) of the semiconductor element 21. Additionally, the semiconductor device A30 has a configuration in common with the semiconductor device A10 and therefore achieves the same advantages as those achieved by the common configuration.

Also, the semiconductor element 21 includes the gate electrode 213 on the same side as the first electrode 211 in the thickness direction z. As viewed in the thickness direction z, the gate electrode 213 overlaps with the first recess 211A in the first electrode 211 of the semiconductor element 21 and the second recess 312C in the first bonding part 312 of the conductive member 30. The configuration can prevent the first bonding part 312 from covering the gate electrode 213 even if misalignment of the conductive member 30 with the first electrode 211 is permitted to some extent.

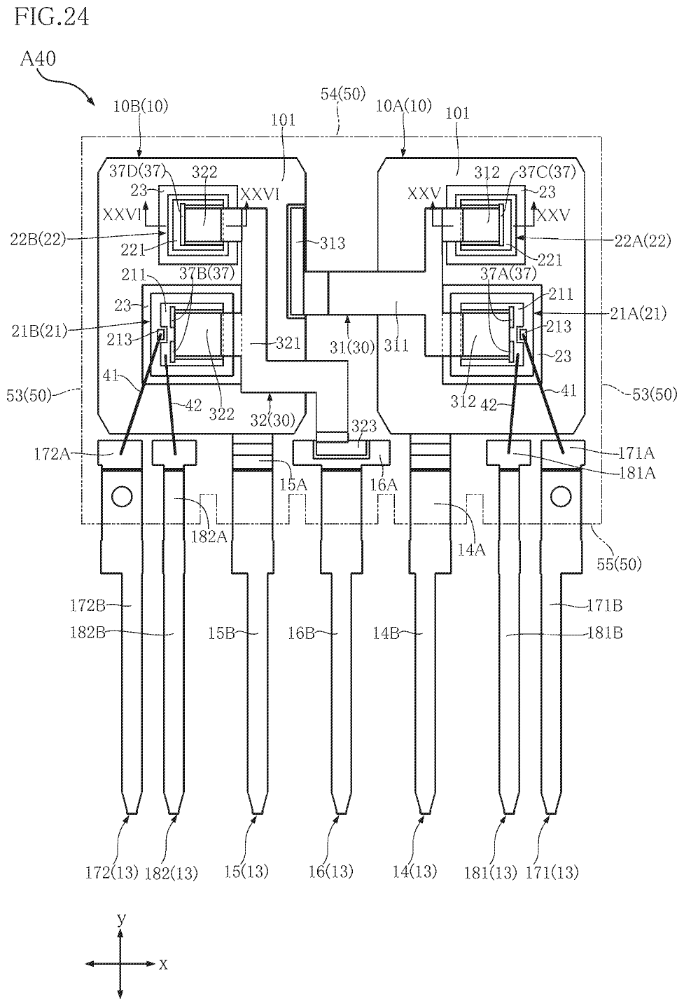

With reference to FIGS. 24 to 26, the following describes a semiconductor device A40 according to a fourth embodiment of the present disclosure. In these figures, the same or similar elements as those of the semiconductor device A10 described above are denoted by the same reference signs, and redundant descriptions of such elements are omitted. For the convenience of description, FIG. 24 shows the sealing resin 50 as transparent. In FIG. 24, the sealing resin 50 is indicated by imaginary lines.

The semiconductor device A40 differs from the semiconductor device A10 in that a protection element 22 is further included. In addition, the configurations of the conductive member 30 and the regulator 37 are different.

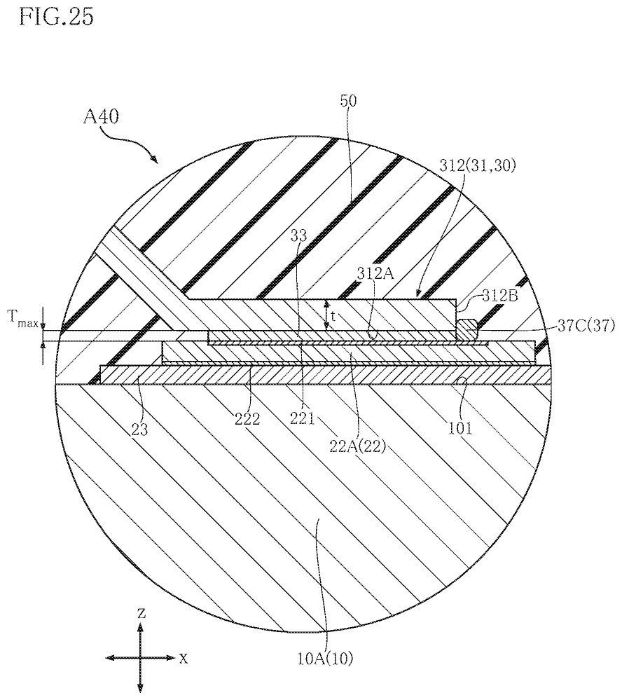

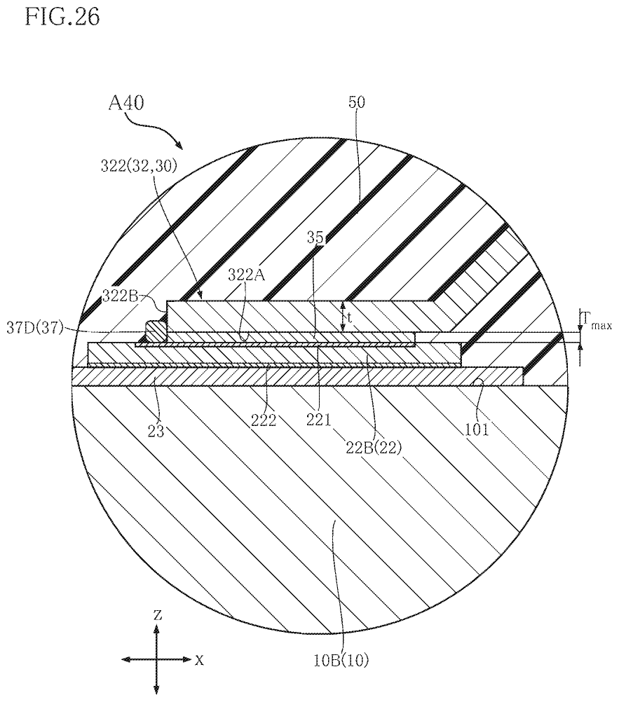

As shown in FIG. 24, the protection element 22 includes a first diode 22A and a second diode 22B. The first diode 22A is mounted on the obverse surface 101 of the first die pad 10A. The second diode 22B is mounted on the obverse surface 101 of the second die pad 10B. The protection element 22 is composed of a Schottky barrier diode, for example. The first diode 22A is connected in parallel to the first element 21A. The second diode 22B is connected in parallel to the second element 21B. The protection element 22 is a so-called reflux diode that passes electric current when a reverse bias is applied to the semiconductor element 21, preventing the current from flowing through the semiconductor element 21. As shown in FIGS. 25 and 26, the protection element 22 includes an upper-surface electrode 221 and a lower-surface electrode 222.

As shown in FIGS. 25 and 26, the upper-surface electrode 221 faces the same side as the obverse surface 101 of the support member 10 faces in the thickness direction z. The upper-surface electrode 221 is an anode electrode.

As shown in FIGS. 25 and 26, the lower-surface electrode 222 is disposed on the side opposite the upper-surface electrode 221 in the thickness direction z. The lower-surface electrode 222 is a cathode electrode. As shown in FIG. 25, the lower-surface electrode 222 of the first diode 22A is bonded to the obverse surface 101 of the first die pad 10A via a die-bonding layer 23. This electrically connects the lower-surface electrode 222 of the first diode 22A to the second electrode 212 of the first element 21A via the first die pad 10A. As shown in FIG. 26, the lower-surface electrode 222 of the second diode 22B is bonded to the obverse surface 101 of the second die pad 10B via a die-bonding layer 23. This electrically connects the lower-surface electrode 222 of the second diode 22B to the second electrode 212 of the second element 21B via the second die pad 10B.

As shown in FIG. 24, the first bonding part 312 of the first conductive member 31 includes two sections spaced apart from each other in the second direction y. As shown in Fig. 25, one of the two sections is bonded to the upper-surface electrode 221 of the first diode 22A via a first bonding layer 33. This electrically connects the upper-surface electrode 221 of the first diode 22A to the first electrode 211 of the first element 21A via the first conductive member 31.

As shown in FIG. 24, the third bonding part 322 of the second conductive member 32 includes two sections spaced apart from each other in the second direction y. As shown in FIG. 26, one of the two sections is bonded to the upper-surface electrode 221 of the second diode 22B via a third bonding layer 35. This electrically connects the upper-surface electrode 221 of the first diode 22A to the first electrode 211 of the second element 21B via the second conductive member 32.

As shown in FIG. 25, the regulator 37 of the semiconductor device A40 further includes a third regulator 37C bonded to the upper-surface electrode 221 of the first diode 22A. The third regulator 37C faces the first bonding layer 33 in the first direction x. The third regulator 37C is in contact with the first bonding layer 33 and the end surface 312B of the first bonding part 312 of the first conductive member 31.

As shown in FIG. 26, the regulator 37 of the semiconductor device A40 further includes a fourth regulator 37D bonded to the upper-surface electrode 221 of the second diode 22B. The fourth regulator 37D faces the third bonding layer 35 in the first direction x. The fourth regulator 37D is in contact with the third bonding layer 35 and the end surface 322B of the third bonding part 322 of the second conductive member 32.

Next, advantages of the semiconductor device A40 will be described.

The semiconductor device A40 includes the semiconductor element 21 (the first element 21A) including the first electrode 211, the conductive member 30 (the first conductive member 31) including the first bonding part 312 facing the semiconductor element 21, and the bonding layer (the first bonding layer 33) interposed between the first electrode 211 and the first bonding part 312. The semiconductor device A40 further includes the regulator 37 (the first regulator 37A) bonded to the first electrode 211. The regulator 37 faces the first bonding layer 33 in a direction orthogonal to the thickness direction z. With this configuration, the semiconductor device A40 achieves the same advantages as those achieved by the semiconductor device A10. The semiconductor device A40 can therefore prevent positional misalignment of the conductive member 30 with the electrode (the first electrode 211) of the semiconductor element 21. Additionally, the semiconductor device A40 has a configuration in common with the semiconductor device A10 and thus achieves the same advantages as those achieved by the common configuration.

The semiconductor device A40 further includes the protection element 22. This provides appropriate protection to the semiconductor element 21 against the reverse bias voltage, which may be caused when a larger current is passed through the semiconductor device A40.

The regulator 37 of the semiconductor device A40 includes the third regulator 37C bonded to the upper-surface electrode 221 of the first diode 22A and the fourth regulator 37D bonded to the upper-surface electrode 221 of the second diode 22B. In the process of bonding the first bonding part 312 of the first conductive member 31 to the first electrode 211 of the first element 21A and to the upper-surface electrode 221 of the first diode 22A each via the first bonding layer 33, the first bonding part 312 may come into contact with at least one of the first regulator 37A and the third regulator 37C. This efficiently prevents the first conductive member 31 from rotating about the thickness direction z. Similarly, in the process of bonding the third bonding part 322 of the second conductive member 32 to the first electrode 211 of the second element 21B and to the upper-surface electrode 221 of the second diode 22B each via the third bonding layer 35, the third bonding part 322 may come into contact with at least one of the second regulator 37B and the fourth regulator 37D. This efficiently prevents the second conductive member 32 from rotating about the thickness direction z.

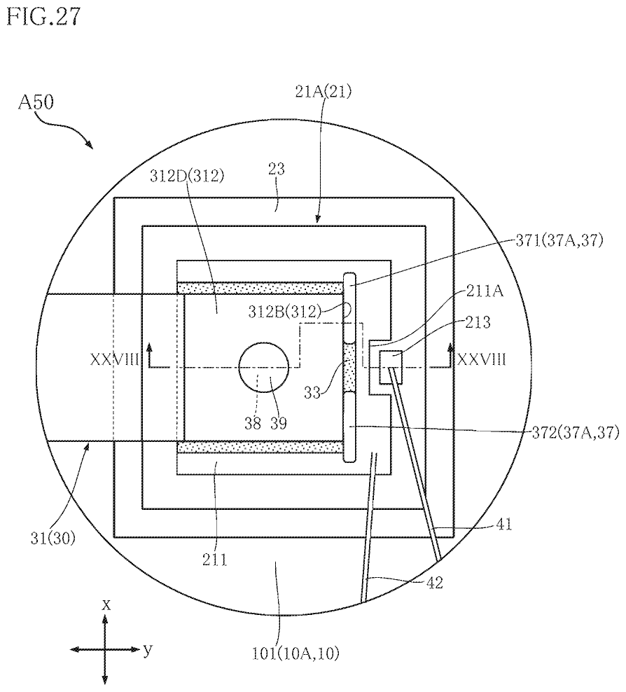

With reference to FIGS. 27 to 30, a semiconductor device A50 according to a fifth embodiment of the present disclosure will be described. In these figures, the same or similar elements as those of the semiconductor device A10 described above are denoted by the same reference signs, and redundant descriptions of such elements are omitted. For the convenience of description, FIGS. 27 and 29 show the sealing resin 50 as transparent. FIG. 27 shows the part that correspond to the part of the semiconductor device A10 shown in FIG. 12. FIG. 29 shows the part corresponding to the part of the semiconductor device A10 shown in FIG. 14.

The semiconductor device A50 differs from the semiconductor device A10 in the configuration of the conductive member 30.

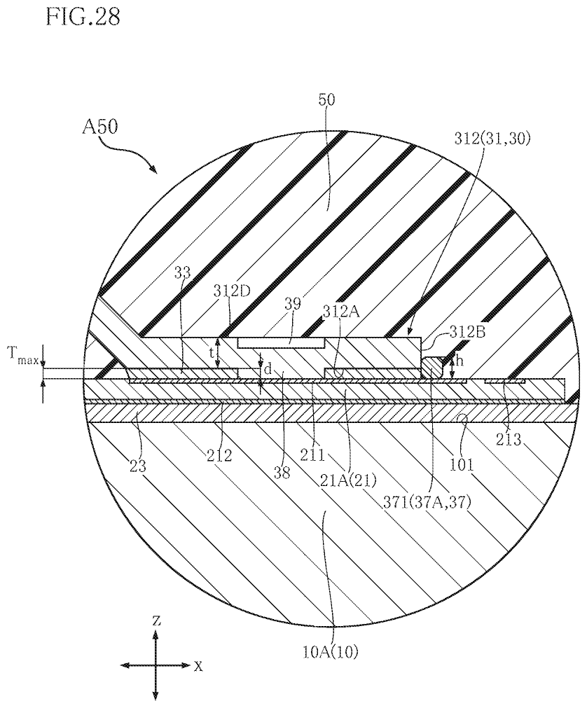

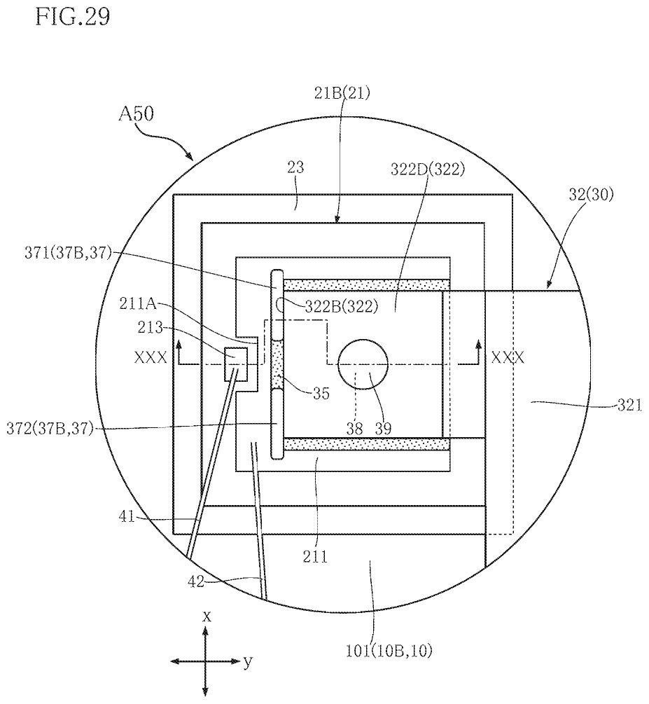

As shown in FIGS. 27 and 28, the first conductive member 31 includes a protrusion 38 and a depression 39. The protrusion 38 and the depression 39 are formed in the first bonding part 312 of the first conductive member 31. The protrusion 38 and the depression 39 may be formed by pressing the first bonding part 312.

As shown in FIG. 28, the protrusion 38 protrudes from the bonding surface 312A of the first bonding part 312 in the thickness direction z toward the first electrode 211 of the first element 21A. The protrusion 38 is in contact with the first electrode 211 of the first element 21A and the first bonding layer 33. The protrusion 38 has a length d in the z direction, and the first regulator 37A has a length h in the thickness direction z, where the length d is less than the length h. As shown in FIG. 27, the protrusion 38 is circular as viewed in the thickness direction z. Alternatively, the protrusion 38 may have a polygonal shape, such as a rectangle, as viewed in the thickness direction.

As shown in FIG. 28, the depression 39 is recessed from the upper surface 312D of the first bonding part 312 in the thickness direction z toward the first electrode 211 of the first element 21A. The upper surface 312D faces away from the bonding surface 312A of the first bonding part 312 in the thickness direction z and is connected to the end surface 312B of the first bonding part 312. As shown in FIG. 27, the depression 39 as viewed in the thickness direction z has a shape similar to the shape of the protrusion 38 as viewed in the thickness direction z. As viewed in the thickness direction z, the depression 39 overlaps with the protrusion 38. In this example, the length d of the protrusion 38 in the thickness direction z is equal to or less than the thickness t of the first bonding part 312.

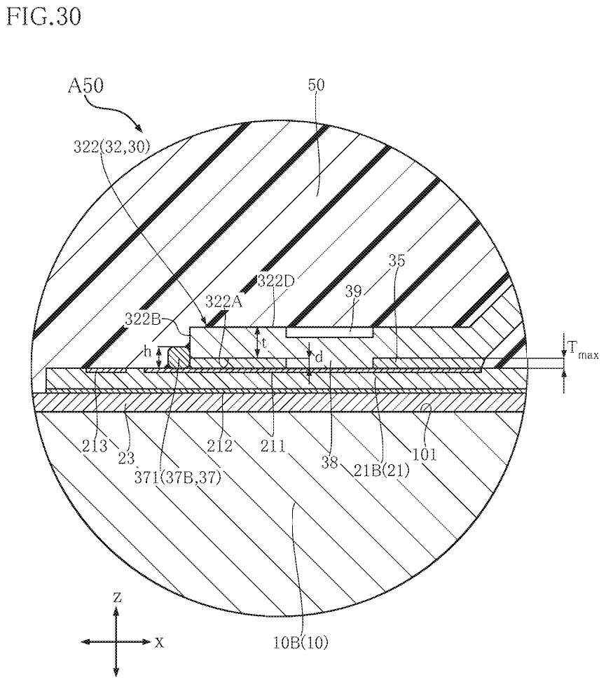

As shown in FIGS. 29 and 30, the second conductive member 32 includes a protrusion 38 and a depression 39. The protrusion 38 and the depression 39 are formed in the third bonding part 322 of the second conductive member 32. The protrusion 38 and the depression 39 may be formed by pressing the third bonding part 322.

As shown in FIG. 30, the protrusion 38 protrudes from the bonding surface 322A of the third bonding part 322 in the thickness direction z toward the first electrode 211 of the second element 21B. The protrusion 38 is in contact with the first electrode 211 of the second element 21B and the third bonding layer 35. The protrusion 38 has a length d in the z direction, and the second regulator 37B has a length h in the thickness direction z, where the length d is less than the length h. As shown in FIG. 29, the protrusion 38 is circular as viewed in the thickness direction z. Alternatively, the protrusion 38 may have a polygonal shape, such as a rectangle, as viewed in the thickness direction.

As shown in FIG. 30, the depression 39 is recessed from the upper surface 322D of the third bonding part 322 in the thickness direction z toward the first electrode 211 of the second element 21B. The upper surface 322D faces away from the bonding surface 322A of the third bonding part 322 in the thickness direction z and is connected to the end surface 322B of the third bonding part 322. As shown in FIG. 29, the depression 39 as viewed in the thickness direction z has a shape similar to the shape of the protrusion 38 as viewed in the thickness direction z. As viewed in the thickness direction z, the depression 39 overlaps with the protrusion 38. In this example, the length d of the protrusion 38 in the thickness direction z is equal to or less than the thickness t of the third bonding part 322.

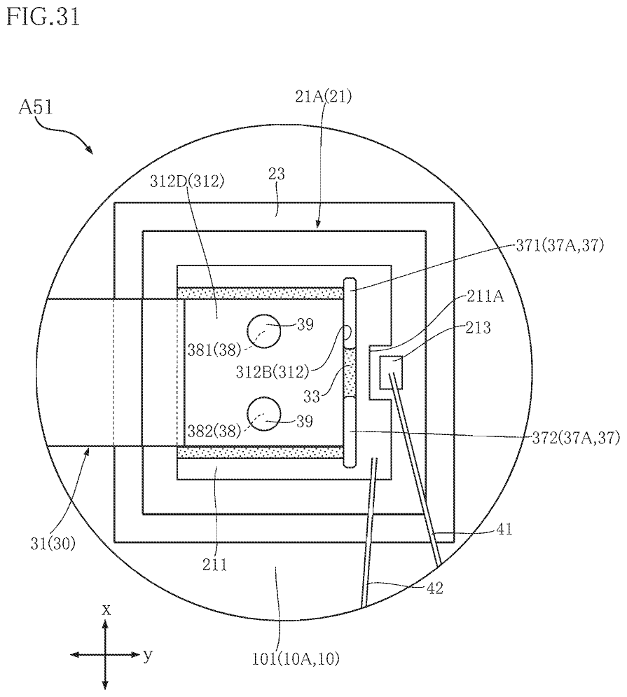

Next, with reference to FIG. 31, the following describes a semiconductor device A51 that is a first variation of the semiconductor device A50. For the convenience of description, FIG. 31 shows the sealing resin 50 as transparent. The part shown in FIG. 31 corresponds to the part shown in FIG. 27. The configuration of this variation described below regarding the first conductive member 31 is also applicable to the second conductive member 32 shown in FIGS. 29 and 30.

As shown in FIG. 31, in the semiconductor device A51, the protrusion 38 of the first conductive member 31 includes a first protrusion 381 and a second protrusion 382 spaced apart from each other in the first direction x. As viewed in the thickness direction z, the first protrusion 381 and the second protrusion 382 are identical in size and shape.

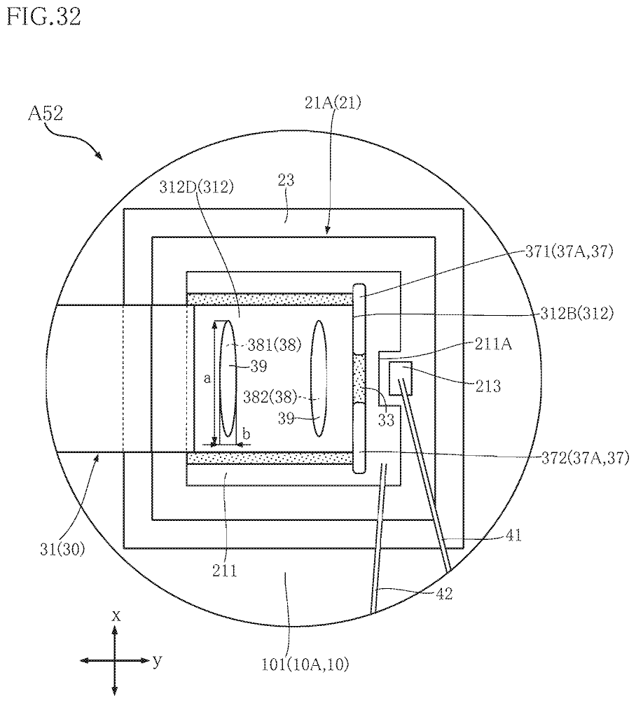

Next, with reference to FIG. 32, the following describes a semiconductor device A52 that is a second variation of the semiconductor device A50. For the convenience of description, FIG. 32 shows the sealing resin 50 as transparent. The part shown in FIG. 32 corresponds to the part shown in FIG. 27. The configuration of this variation described below regarding the first conductive member 31 is also applicable to the second conductive member 32 shown in FIGS. 29 and 30.

As shown in FIG. 32, in the semiconductor device A52, the protrusion 38 of the first conductive member 31 includes a first protrusion 381 and a second protrusion 382 spaced apart from each other in the second direction y. Each of the first protrusion 381 and the second protrusion 382 extends in the first direction x. That is, each of the first protrusion 381 and the second protrusion 382 extends in the direction orthogonal to both the thickness direction z and the direction in which the first protrusion 381 and the second protrusion 382 are spaced apart from each other. Each of the first protrusion 381 and the second protrusion 382 has a length a in the first direction x and a length b in the second direction y, where the length a is greater than the length b. As viewed in the thickness direction z, the first protrusion 381 and the second protrusion 382 are identical in size and shape.

Next, advantages of the semiconductor device A50 will be described.

The semiconductor device A50 includes the semiconductor element 21 (the first element 21A) including the first electrode 211, the conductive member 30 (the first conductive member 31) including the first bonding part 312 facing the semiconductor element 21, and the bonding layer (the first bonding layer 33) interposed between the first electrode 211 and the first bonding part 312. The semiconductor device A50 further includes the regulator 37 (the first regulator 37A) bonded to the first electrode 211. The regulator 37 faces the first bonding layer 33 in a direction orthogonal to the thickness direction z. With this configuration, the semiconductor device A50 achieves the same advantages as those achieved by the semiconductor device A10. The semiconductor device A50 can therefore prevent positional misalignment of the conductive member 30 with the electrode (the first electrode 211) of the semiconductor element 21. Additionally, the semiconductor device A50 has a configuration in common with the semiconductor device A10 and thus achieves the same advantages as those achieved by the common configuration.

The conductive member 30 of the semiconductor device A50 includes the protrusion 38 in the first bonding part 312. The protrusion 38 protrudes in the thickness direction z toward the first electrode 211 of the semiconductor element 21. The protrusion 38 is in contact with the first electrode 211. With this configuration, the protrusion 38 serves as a spacer when the first bonding part 312 is bonded to the first electrode 211 via the first bonding layer 33. Consequently, the maximum thickness Tₘₐₓ of the first bonding layer 33 shown in FIG. 28 is made equal to (or substantially equal to) the length d of the protrusion 38 in the thickness direction z. In this way, the maximum thickness Tₘₐₓ can be controlled. The first bonding layer 33 having the appropriate maximum thickness Tₘₐₓ enables the semiconductor device A50 to be more durable and withstand temperature cycles and power cycles. Additionally, the first bonding layer 33 can be less prone to voids.

Additionally, the protrusion 38 shown in FIG. 28 has the length d in the z direction that is less than the length h of the regulator 37 in the thickness direction z. This configuration ensures that the end surface 312B of the first bonding part 312 comes into contact with the regulator 37 when the first bonding part 312 is forced to move in the first direction x toward the gate electrode 213 of the semiconductor element 21 in the process of bonding the first bonding part 312 to the first electrode 211 via the first bonding layer 33. To achieve this effect, the length d of the protrusion 38 in the thickness direction z is preferably within a range of 75 μm and 175 μm. More preferably, the length d is within a range of 100 μm and 150 μm.

In the semiconductor device A51, the protrusion 38 includes the first protrusion 381 and the second protrusion 382 spaced apart from each other in the first direction x. This configuration prevents the first bonding part 312 from rotating about the second direction y in the process of bonding the first bonding part 312 of the conductive member 30 to the first electrode 211 of the semiconductor element 21 via the first bonding layer 33.

In the semiconductor device A52, the protrusion 38 includes the first protrusion 381 and the second protrusion 382 each of which extends in the direction orthogonal to both the thickness direction z and the direction in which the first protrusion 381 and the second protrusion 382 are spaced apart from each other. This configuration prevents the first bonding part 312 from rotating about both the first direction x and the second direction y in the process of bonding the first bonding part 312 of the conductive member 30 to the first electrode 211 of the semiconductor element 21 via the first bonding layer 33.

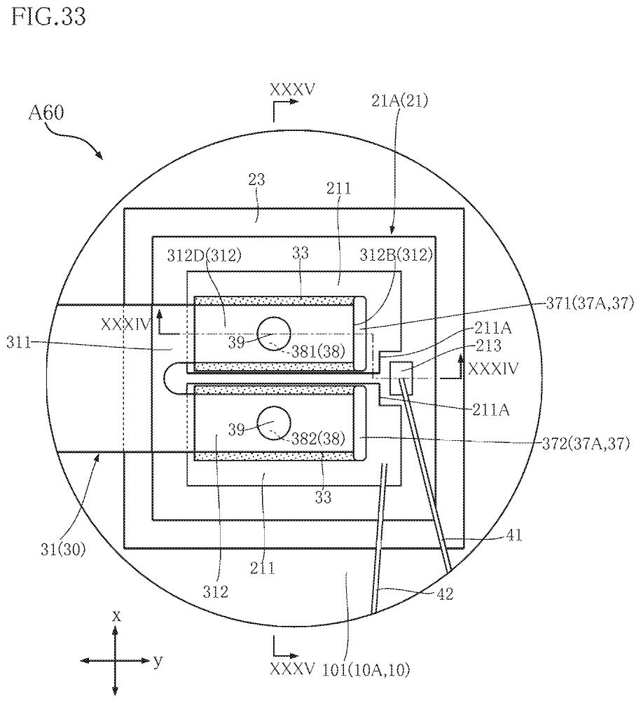

With reference to FIGS. 33 to 35, a semiconductor device A60 according to a sixth embodiment of the present disclosure will be described. In these figures, the same or similar elements as those of the semiconductor device A10 described above are denoted by the same reference signs, and redundant descriptions of such elements are omitted. For the convenience of description, FIG. 33 shows the sealing resin 50 as transparent. FIG. 33 shows the part that correspond to the part of the semiconductor device A50 shown in FIG. 27. The configuration of this variation regarding the first electrode 211 of the first element 21A and the first conductive member 31 described below is also applicable to the first electrode 211 of the second element 21B and the second conductive member 32 shown in FIGS. 29 and 30.

The semiconductor device A60 differs from the semiconductor device A50 in the configurations of the semiconductor element 21 and the conductive member 30.

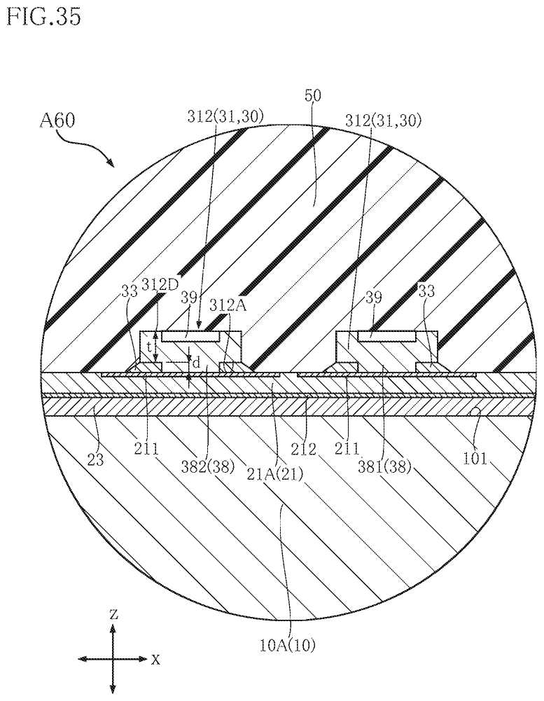

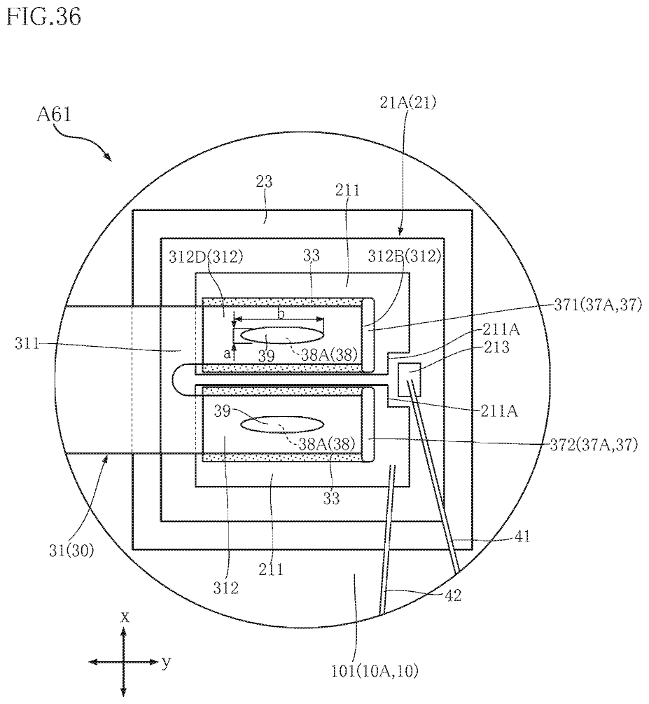

As shown in FIGS. 33 and 35, the first electrode 211 of the first element 21A includes two sections spaced apart from each other in the first direction x. The first conductive member 31 correspondingly includes two first bonding parts 312 spaced apart from each other in the first direction x. Each first bonding part 312 has an end in the second direction y connected to the main part 311 of the first conductive member 31.

As shown in FIGS. 33 to 35, the first conductive member 31 includes a protrusion 38 and a depression 39. The protrusion 38 and the depression 39 are formed in each of the two first bonding parts 312 of the first conductive member 31.

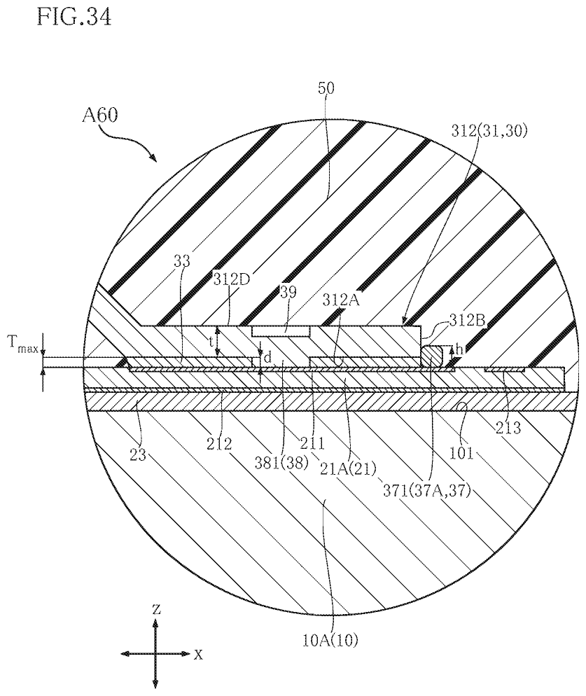

As shown in FIGS. 34 and 35, the protrusion 38 protrudes from the bonding surface 312A of the first bonding part 312 in the thickness direction z toward the first electrode 211 of the first element 21A. The protrusion 38 is in contact with the first electrode 211 of the first element 21A and the first bonding layer 33. The protrusion 38 includes a first protrusion 381 and a second protrusion 382 spaced apart from each other in the first direction x. The first protrusion 381 is formed in one of the two first bonding parts 312. The second protrusion 382 is formed in the other of the two first bonding parts 312. As shown in FIG. 33, the first protrusion 381 and the second protrusion 382 are identical in size and shape as viewed in the thickness direction z. Each of the first protrusion 381 and the second protrusion 382 has a length d in the z direction, and the first regulator 37A has a length h in the thickness direction z, where the length d is less than the length h. Preferably, the length d of each of the first protrusion 381 and the second protrusion 382 in the thickness direction z is within a range of 75 μm and 175 μm. More preferably, the length d is within a range of 100 μm and 150 μm. Other than the points described above, the protrusion 38 of this embodiment is similar in configuration to the protrusion 38 of the first conductive member 31 of the semiconductor device A50.

The depression 39 is recessed from the upper surface 312D of the first bonding part 312 in the thickness direction z toward the first electrode 211 of the first element 21A. The upper surface 312D faces away from the bonding surface 312A of the first bonding part 312 in the thickness direction z and is connected to the end surface 312B of the first bonding part 312. Other than the points described above, the depression 39 of this embodiment is similar in configuration to the depression 39 in the first conductive member 31 of the semiconductor device A50.

Next, with reference to FIG. 36, the following describes a semiconductor device A61 that is a variation of the semiconductor device A60. For the convenience of description, FIG. 36 shows the sealing resin 50 as transparent. The part shown in FIG. 36 corresponds to the part shown in FIG. 33. The configuration of this variation described below regarding the first conductive member 31 is also applicable to the second conductive member 32 shown in FIGS. 29 and 30.

As shown in FIG. 36, in the semiconductor device A61, the protrusion 38 of the first conductive member 31 includes a first protrusion 381 and a second protrusion 382 extending in the first direction x. That is, the first protrusion 381 and the second protrusion 382 extend in the direction orthogonal to both the thickness direction z and the direction in which the first protrusion 381 and the second protrusion 382 are spaced apart from each other. Each of the first protrusion 381 and the second protrusion 382 has a length a in the first direction x and a length b in the second direction y, where the length a is greater than the length b.

Next, advantages of the semiconductor device A60 will be described.

The semiconductor device A60 includes the semiconductor element 21 (the first element 21A) including the first electrode 211, the conductive member 30 (the first conductive member 31) including the first bonding part 312 facing the semiconductor element 21, and the bonding layer (the first bonding layer 33) interposed between the first electrode 211 and the first bonding part 312. The semiconductor device A60 further includes the regulator 37 (the first regulator 37A) bonded to the first electrode 211. The regulator 37 faces the first bonding layer 33 in a direction orthogonal to the thickness direction z. With this configuration, the semiconductor device A60 achieves the same advantages as those achieved by the semiconductor device A10. The semiconductor device A60 can therefore prevent positional misalignment of the conductive member 30 with the electrode (the first electrode 211) of the semiconductor element 21. Additionally, the semiconductor device A60 has a configuration in common with the semiconductor device A10 and thus achieves the same advantages as those achieved by the common configuration.

The conductive member 30 of the semiconductor device A60 includes the protrusion 38 in each of the two first bonding parts 312. The protrusion 38 protrudes in the thickness direction z toward the first electrode 211 of the semiconductor element 21. The protrusion 38 is in contact with the first electrode 211. That is, the semiconductor device A60 is provided with the first bonding layer 33 having the maximum thickness Tₘₐₓ appropriately controlled as shown in FIG. 34. The semiconductor device A60 is therefore more durable and able to withstand temperature cycles and power cycles. Additionally, the first bonding layer 33 can be less prone to voids.

The protrusion 38 includes the first protrusion 381 and the second protrusion 382 spaced apart from each other in the first direction x. This configuration prevents each first bonding part 312 from rotating about the second direction y in the process of bonding the first bonding part 312 of the conductive member 30 to the first electrode 211 of the semiconductor element 21 via the first bonding layer 33.

In the semiconductor device A61, each of the first protrusion 381 and the second protrusion 382 extends in the direction orthogonal to both the thickness direction z and the direction in which the first protrusion 381 and the second protrusion 382 are spaced apart from each other. This configuration prevents the first bonding part 312 from rotating about both the first direction x and the second direction y in the process of bonding the first bonding part 312 of the conductive member 30 to the first electrode 211 of the semiconductor element 21 via the first bonding layer 33.

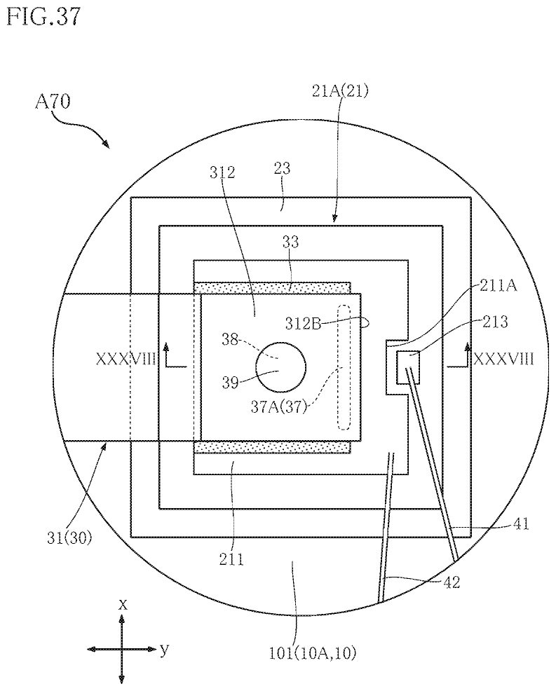

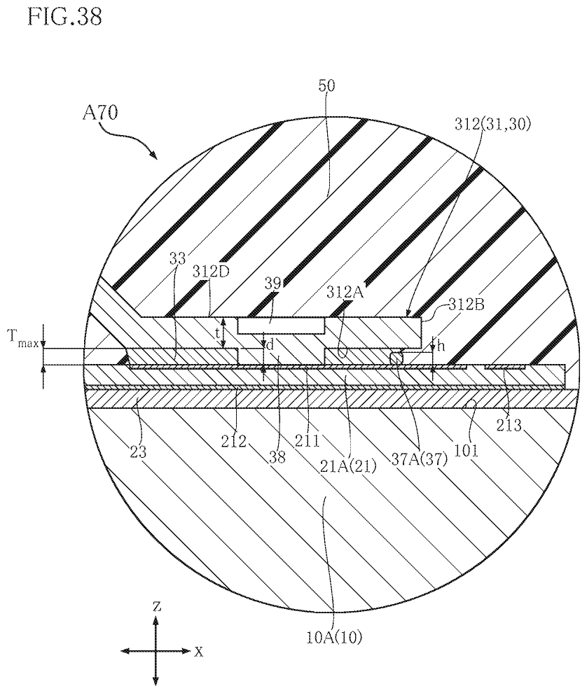

With reference to FIGS. 37 and 38, the following describes a semiconductor device A70 according to a seventh embodiment of the present disclosure. In these figures, the same or similar elements as those of the semiconductor device A10 described above are denoted by the same reference signs, and redundant descriptions of such elements are omitted. For the convenience of description, FIG. 37 shows the sealing resin 50 as transparent. FIG. 37 shows the part corresponding to the part of the semiconductor device A20 shown in FIG. 16. The configuration of this embodiment regarding the first conductive member 31 and the first regulator 37A described below is also applicable to the second conductive member 32 and the second regulator 37B shown in FIGS. 18 and 19.

The semiconductor device A70 differs from the semiconductor device A20 in the configurations of the conductive member 30 and the regulator 37.

As shown in FIGS. 37 and 38, the first conductive member 31 includes a protrusion 38 and a depression 39. The protrusion 38 and the depression 39 are formed in the first bonding part 312 of the first conductive member 31. The protrusion 38 and the depression 39 may be formed by pressing the first bonding part 312.

As shown in FIG. 38, the protrusion 38 protrudes from the bonding surface 312A of the first bonding part 312 in the thickness direction z toward the first electrode 211 of the first element 21A. The protrusion 38 is in contact with the first electrode 211 of the first element 21A and the first bonding layer 33. The protrusion 38 has a length d in the z direction, and the first regulator 37A has a length h in the thickness direction z, where the length d is greater than the length h. As shown in FIG. 37, the protrusion 38 is circular as viewed in the thickness direction z. Alternatively, the protrusion 38 may have a polygonal shape, such as a rectangle, as viewed in the thickness direction.

As shown in FIG. 38, the depression 39 is recessed from the upper surface 312D of the first bonding part 312 in the thickness direction z toward the first electrode 211 of the first element 21A. The upper surface 312D faces away from the bonding surface 312A of the first bonding part 312 in the thickness direction z and is connected to the end surface 312B of the first bonding part 312. As shown in FIG. 37, the depression 39 as viewed in the thickness direction z has a shape similar to the shape of the protrusion 38 as viewed in the thickness direction z. As viewed in the thickness direction z, the depression 39 overlaps with the protrusion 38. In this example, the length d of the protrusion 38 in the thickness direction z is equal to or less than the thickness t of the first bonding part 312.

In the semiconductor device A70, the regulator 37 is formed during the fabrication of the semiconductor element 21 by bonding a piece of metal to the first electrode 211 of the semiconductor element 21. The metal piece can be formed by wire bonding.

Next, advantages of the semiconductor device A70 will be described.

The semiconductor device A70 includes the semiconductor element 21 (the first element 21A) including the first electrode 211, the conductive member 30 (the first conductive member 31) including the first bonding part 312 facing the semiconductor element 21, and the bonding layer (the first bonding layer 33) interposed between the first electrode 211 and the first bonding part 312. The semiconductor device A70 further includes the regulator 37 (the first regulator 37A) bonded to the first bonding part 312. The regulator 37 faces the first bonding layer 33 in a direction orthogonal to the thickness direction z. With this configuration, the first bonding layer 33 in a molten state comes into contact with the regulator 37 in the process of bonding the first bonding part 312 to the first electrode 211 via the first bonding layer 33. The regulator 37 thus prevents the first bonding layer 33 from flowing further and applies a reaction force pushing the first bonding part 312 in the opposite direction to the flow direction. This prevents the first bonding part 312 from deviating relative to the first electrode 211. The semiconductor device A70 can therefore prevent positional misalignment of the conductive member 30 with the electrode (the first electrode 211) of the semiconductor element 21. Additionally, the semiconductor device A70 has a configuration in common with the semiconductor device A10 and thus achieves the same advantages as those achieved by the common configuration.

The conductive member 30 of the semiconductor device A70 includes the protrusion 38 in the first bonding part 312. The protrusion 38 protrudes in the thickness direction z toward the first electrode 211 of the semiconductor element 21. The protrusion 38 is in contact with the first electrode 211. That is, the semiconductor device A70 is provided with the first bonding layer 33 having the maximum thickness Tₘₐₓ appropriately controlled as shown in FIG. 38. The semiconductor device A70 is therefore more durable and able to withstand temperature cycles and power cycles. Additionally, the first bonding layer 33 can be less prone to voids.

Additionally, the protrusion 38 shown in FIG. 38 has the length d in the z direction that is greater than the length h of the regulator 37 in the thickness direction z. With this configuration, the regulator 37 does not obstruct the protrusion 38 from moving into contact with the first electrode 211 in the process of bonding the first bonding part 312 to the first electrode 211 via the first bonding layer 33. Additionally, the regulator 37 applies a reaction force to the first bonding layer 33 when the first bonding layer 33 in a molten state comes into contact with the regulator 37. The reaction force acts on the protrusion 38. This efficiently prevents the first bonding part 312 from deviating relative to the first electrode 211.

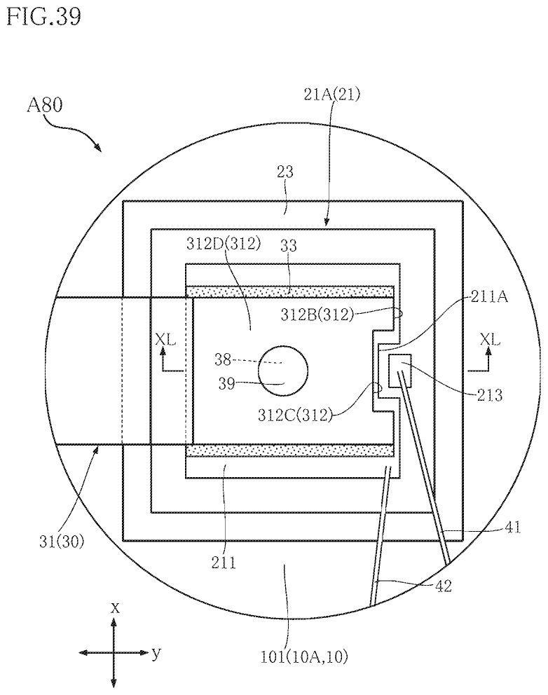

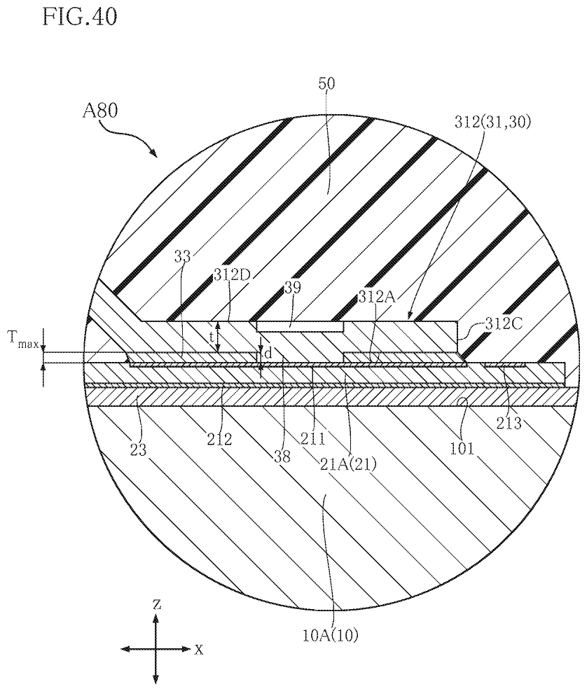

With reference to FIGS. 39 and 40, the following describes a semiconductor device A80 according to an eighth embodiment of the present disclosure. In these figures, the same or similar elements as those of the semiconductor device A10 described above are denoted by the same reference signs, and redundant descriptions of such elements are omitted. For the convenience of description, FIG. 39 shows the sealing resin 50 as transparent. FIG. 39 shows the part that correspond to the part of the semiconductor device A30 shown in FIG. 22. The configuration of this variation described below regarding the first conductive member 31 is also applicable to the second conductive member 32 shown in FIG. 23.

The semiconductor device A80 differs from the semiconductor device A30 in the configuration of the conductive member 30.

As shown in FIGS. 39 and 40, the first conductive member 31 includes a protrusion 38 and a depression 39. The protrusion 38 and the depression 39 are formed in the first bonding part 312 of the first conductive member 31. The protrusion 38 and the depression 39 may be formed by pressing the first bonding part 312.

As shown in FIG. 40, the protrusion 38 protrudes from the bonding surface 312A of the first bonding part 312 in the thickness direction z toward the first electrode 211 of the first element 21A. The protrusion 38 is in contact with the first electrode 211 of the first element 21A and the first bonding layer 33. As shown in FIG. 39, the protrusion 38 is circular as viewed in the thickness direction z. Alternatively, the protrusion 38 may be have a polygonal shape, such as a rectangle, as viewed in the thickness direction.

As shown in FIG. 40, the depression 39 is recessed from the upper surface 312D of the first bonding part 312 in the thickness direction z toward the first electrode 211 of the first element 21A. The upper surface 312D faces away from the bonding surface 312A of the first bonding part 312 in the thickness direction z and is connected to the end surface 312B of the first bonding part 312. As shown in FIG. 39, the depression 39 as viewed in the thickness direction z has a shape similar to the shape of the protrusion 38 as viewed in the thickness direction z. As viewed in the thickness direction z, the depression 39 overlaps with the protrusion 38. In this example, the length d of the protrusion 38 in the thickness direction z is equal to or less than the thickness t of the first bonding part 312.

Next, advantages of the semiconductor device A80 will be described.

The semiconductor device A80 includes the semiconductor element 21 (the first element 21A) including the first electrode 211, a conductive member 30 (the first conductive member 31) including the first bonding part 312 facing the semiconductor element 21, and the bonding layer (the first bonding layer 33) interposed between the first electrode 211 and the first bonding part 312. The first electrode 211 is formed with the first recess 211A recessed in a direction orthogonal to the thickness direction z. The first bonding part 312 is formed with a second recess 312C recessed in a direction orthogonal to the thickness direction z. As viewed in the thickness direction z, the second recess 312C overlaps with the first recess 211A. The semiconductor device A80 can therefore prevent positional misalignment of the conductive member 30 with the electrode (the first electrode 211) of the semiconductor element 21. Additionally, the semiconductor device A80 has a configuration in common with the semiconductor device A10 and thus achieves the same advantages as those achieved by the common configuration.

The conductive member 30 of the semiconductor device A80 includes the protrusion 38 in the first bonding part 312. The protrusion 38 protrudes in the thickness direction z toward the first electrode 211 of the semiconductor element 21. The protrusion 38 is in contact with the first electrode 211. That is, the semiconductor device A80 is provided with the first bonding layer 33 having the maximum thickness Tₘₐₓ appropriately controlled as shown in FIG. 40. The semiconductor device A80 is therefore more durable and able to withstand temperature cycles and power cycles. Additionally, the first bonding layer 33 can be less prone to voids.

The present disclosure is not limited to the embodiments set forth above. Various design changes can be made to the specific configuration of each part of the present disclosure.

The present disclosure includes the embodiments described in the following clauses.

Clause 1. A semiconductor device comprising:

a semiconductor element including a first electrode;

a conductive member including a first bonding part facing the first electrode;

a bonding layer interposed between the first electrode and the first bonding part; and

a regulator bonded to at least one of the first electrode and the first bonding part,

wherein the regulator faces the bonding layer in a direction orthogonal to a thickness direction of the semiconductor element.

Clause 2. The semiconductor device according to Clause 1, wherein the regulator contains a metallic element.

Clause 3. The semiconductor device according to Clause 2, wherein the metallic element is aluminum.

Clause 4. The semiconductor device according to Clause 2 or 3, wherein the regulator is bonded to the first electrode,

the first bonding part includes an end surface facing in a first direction orthogonal to the thickness direction, and

the end surface is in contact with the regulator.

Clause 5. The semiconductor device according to Clause 4, wherein the regulator includes a first part and a second part spaced apart from each other in a second direction orthogonal to the thickness direction and the first direction.

Clause 6. The semiconductor device according to Clause 5, wherein a part of the bonding layer is located between the first part and the second part.

Clause 7. The semiconductor device according to Clause 2 or 3, wherein the first bonding part includes a bonding surface facing the first electrode,

the regulator is bonded to the bonding surface, and

the regulator is in contact with the first electrode.

Clause 8. The semiconductor device according to Clause 7, wherein the conductive member includes an end part connected to the first bonding part,

the end part is inclined relative to the bonding surface to be increasingly away from the first electrode in the thickness direction with an increase in a distance from the first bonding part in a direction orthogonal to the thickness direction, and

the first electrode includes an extension part located on a side opposite the first bonding part with the end part in between as viewed in the thickness direction.

Clause 9. The semiconductor device according to any one of Clauses 1 to 8, wherein the regulator is in contact with the bonding layer.

Clause 10. The semiconductor device according to any one of Clauses 1 to 9, wherein the semiconductor element includes a gate electrode located on a same side as the first electrode in the thickness direction, and

a part of the first electrode is located between the gate electrode and the first bonding part as viewed in the thickness direction.

Clause 11. A semiconductor device comprising:

a semiconductor element including a first electrode;

a conductive member including a first bonding part facing the first electrode; and

a bonding layer interposed between the first electrode and the first bonding part,

wherein the first electrode includes a first recess that is recessed in a direction orthogonal to a thickness direction of the semiconductor element,

the first bonding part includes a second recess that is recessed in a direction orthogonal to the thickness direction, and

the second recess overlaps with the first recess as viewed in the thickness direction.

Clause 12. The semiconductor device according to Clause 11, wherein the semiconductor element includes a gate electrode located on a same side as the first electrode in the thickness direction, and

the gate electrodes overlaps with the first recess and the second recess as viewed in the thickness direction.

Clause 13. The semiconductor device according to any one of Clauses 1 to 12, further comprising a support member located on a side opposite the first bonding part with respect to the semiconductor element in the thickness direction,

wherein the semiconductor element is mounted on the support member.

Clause 14. The semiconductor device according to Clause 13, further comprising a sealing resin covering the semiconductor element, the conductive member and a part of the support member.

Clause 15. The semiconductor device according to Clause 14, further comprising a plurality of terminal leads electrically connected to the semiconductor element,

wherein a part of each of the plurality of terminal leads is covered with the sealing resin.

Clause 16. The semiconductor device according to Clause 15, wherein the support member is electrically conductive,

the semiconductor element includes a second electrode facing the support member,

the second electrode is bonded to the support member, and

at least one of the plurality of terminal leads is connected to the support member.

Clause 17. The semiconductor device according to Clause 15 or 16, wherein the conductive member includes a main part connected to the first bonding part and a second bonding part connected to the main part and spaced apart from the first bonding part, and

the second bonding part is bonded to at least one of the plurality of terminal leads.

Clause 18. The semiconductor device according to any one of Clauses 1 to 17, wherein the conductive member includes a protrusion formed in the first bonding part and protruding in the thickness direction toward the first electrode, and

the protrusion is in contact with the first electrode.

Clause 19. The semiconductor device according to Clause 18, wherein the conductive member includes a depression formed in the first bonding part and recessed in the thickness direction toward the first electrode, and

the depression overlaps with the protrusion as viewed in the thickness direction.

Clause 20. The semiconductor device according to Clause 19, wherein a length of the protrusion in the thickness direction is equal to or less than a thickness of the first bonding part.

Clause 21. The semiconductor device according to any one of Clauses 18 to 20, wherein the protrusion comprises a first protrusion and a second protrusion spaced apart from each other in a direction orthogonal to the thickness direction, and

the first protrusion and the second protrusion extend in a direction orthogonal to both of the thickness direction and the direction in which the first protrusion and the second protrusion are spaced apart from each other.

### REFERENCE SIGNS

A10, A20, A30, A40, A50, A60, A70, A80: Semiconductor device

10: Support member 10A: First die pad

10B: Second die pad 101: Obverse surface

102: Reverse surface 103: First seating surface

104: First upstanding surface 13: Terminal lead

14: First input terminal 14A: Covered part

14B: Exposed part 15: Output terminal

15A: Covered part 15B: Exposed part

16: Second input terminal 16A: Covered part

16B: Exposed part 16C: Second seating surface

16D: Second upstanding surface 171: First gate terminal

171A: Covered part 171B: Exposed part

172: Second gate terminal 172A: Covered part

172B: Exposed part 181: First detection terminal

181A: Covered part 181B: Exposed part

182: Second detection terminal 182A: Exposed part

182B: Exposed part 21: Semiconductor element

21A: First element 21B: Second element

211: First electrode 211A: First recess

211B: Extension part 212: Second electrode

213: Gate electrode 22: Protection element

22A: First diode 22B: Second diode

221: Upper-surface electrode 222: Lower-surface electrode

23: Die-bonding layer 31: First conductive member

311: Main part 312: First bonding part

312A: Bonding surface 312B: End surface

312C: Second recess 312D: Upper surface

313: Second bonding part 314: End part

32: Second conductive member 321: Main part

322: Third bonding part 322A: Bonding surface

322B: End surface 322C: Second recess

322D: Upper surface 323: Fourth bonding part

33: First bonding layer 34: Second bonding layer

35: Third bonding layer 36: Fourth bonding layer

37: Regulator 37A: First regulator

37B: Second regulator 37C: Third regulator

37D: Fourth regulator 371: First part

372: Second part 38: Protrusion

381: First protrusion 382: second protrusion

39: Depression 41: Gate wire

42: Detection wire 50: Sealing resin

51: Top surface 52: Bottom surface

53: First side surface 54: Second side surface

55: Third side surface 56: Recess

57: Trench z: Thickness direction

x: First direction y: Second direction

1. A semiconductor device comprising:
a semiconductor element including a first electrode;
a conductive member including a first bonding part facing the first electrode;
a bonding layer interposed between the first electrode and the first bonding part; and
a regulator bonded to at least one of the first electrode and the first bonding part,
wherein the regulator faces the bonding layer in a direction orthogonal to a thickness direction of the semiconductor element.

2. The semiconductor device according to claim 1, wherein the regulator contains a metallic element.

3. The semiconductor device according to claim 2, wherein the metallic element is aluminum.

4. The semiconductor device according to claim 2, wherein the regulator is bonded to the first electrode,
the first bonding part includes an end surface facing in a first direction orthogonal to the thickness direction, and
the end surface is in contact with the regulator.

5. The semiconductor device according to claim 4, wherein the regulator includes a first part and a second part spaced apart from each other in a second direction orthogonal to the thickness direction and the first direction.

6. The semiconductor device according to claim 5, wherein a part of the bonding layer is located between the first part and the second part.

7. The semiconductor device according to claim 2, wherein the first bonding part includes a bonding surface facing the first electrode,
the regulator is bonded to the bonding surface, and
the regulator is in contact with the first electrode.

8. The semiconductor device according to claim 7, wherein the conductive member includes an end part connected to the first bonding part,
the end part is inclined relative to the bonding surface to be increasingly away from the first electrode in the thickness direction with an increase in a distance from the first bonding part in a direction orthogonal to the thickness direction, and
the first electrode includes an extension part located on a side opposite the first bonding part with the end part in between as viewed in the thickness direction.

9. The semiconductor device according to claim 1, wherein the regulator is in contact with the bonding layer.

10. The semiconductor device according to claim 1, wherein the semiconductor element includes a gate electrode located on a same side as the first electrode in the thickness direction, and
a part of the first electrode is located between the gate electrode and the first bonding part as viewed in the thickness direction.

11. A semiconductor device comprising:
a semiconductor element including a first electrode;
a conductive member including a first bonding part facing the first electrode; and
a bonding layer interposed between the first electrode and the first bonding part,
wherein the first electrode includes a first recess that is recessed in a direction orthogonal to a thickness direction of the semiconductor element,
the first bonding part includes a second recess that is recessed in a direction orthogonal to the thickness direction, and
the second recess overlaps with the first recess as viewed in the thickness direction.

12. The semiconductor device according to claim 11, wherein the semiconductor element includes a gate electrode located on a same side as the first electrode in the thickness direction, and
the gate electrodes overlaps with the first recess and the second recess as viewed in the thickness direction.

13. The semiconductor device according to claim 1, further comprising a support member located on a side opposite the first bonding part with respect to the semiconductor element in the thickness direction,
wherein the semiconductor element is mounted on the support member.

14. The semiconductor device according to claim 13, further comprising a sealing resin covering the semiconductor element, the conductive member and a part of the support member.

15. The semiconductor device according to claim 14, further comprising a plurality of terminal leads electrically connected to the semiconductor element,
wherein a part of each of the plurality of terminal leads is covered with the sealing resin.

16. The semiconductor device according to claim 15, wherein the support member is electrically conductive,
the semiconductor element includes a second electrode facing the support member,
the second electrode is bonded to the support member, and
at least one of the plurality of terminal leads is connected to the support member.

17. The semiconductor device according to claim 15, wherein the conductive member includes a main part connected to the first bonding part and a second bonding part connected to the main part and spaced apart from the first bonding part, and
the second bonding part is bonded to at least one of the plurality of terminal leads.

18. The semiconductor device according to claim 1, wherein the conductive member includes a protrusion formed in the first bonding part and protruding in the thickness direction toward the first electrode, and
the protrusion is in contact with the first electrode.

19. The semiconductor device according to claim 18, wherein the conductive member includes a depression formed in the first bonding part and recessed in the thickness direction toward the first electrode, and
the depression overlaps with the protrusion as viewed in the thickness direction.

20. The semiconductor device according to claim 19, wherein a length of the protrusion in the thickness direction is equal to or less than a thickness of the first bonding part.

21. The semiconductor device according to claim 18, wherein the protrusion comprises a first protrusion and a second protrusion spaced apart from each other in a direction orthogonal to the thickness direction, and
the first protrusion and the second protrusion extend in a direction orthogonal to both of the thickness direction and the direction in which the first protrusion and the second protrusion are spaced apart from each other.
